(19) United States
(12) Patent Application Publication
(10) Pub. No.: US 2024/0410760 A1
(43) Pub. Date: Dec. 12, 2024

(54) THERMAL IMAGING FOR ANALYSIS OF DEVICE FABRICATION TOOLS

(71) Applicant: Lam Research Corporation, Fremont, CA (US)

(72) Inventors: Karl Frederick Leeser, West Linn, OR (US); Michal Danek, Cupertino, CA (US); Benjamin Allen Haskell, Pleasanton, CA (US); Kapu Sirish Reddy, Portland, OR (US); Paul Franzen, West Linn, OR (US); Yukinori Sakiyama, West Linn, OR (US); Kapil Sawlani, Ann Arbor, MI (US)

(21) Appl. No.: 18/701,900

(22) PCT Filed: Oct. 27, 2022
(86) PCT No.: PCT/US2022/078791

§ 371 Date: Apr. 16, 2024

Related U.S. Application Data
(60) Provisional application No. 63/263,232, filed on Oct. 28, 2021.

(51) Int. Cl. G01J 5/48; C23C 16/02; C23C 16/455; C23C 16/458; C23C 16/50; C23C 16/52; G01J 5/00; G01J 5/08; G01M 3/38; G06T 7/00; G06T 7/13; H04N 23/23

(52) U.S. Cl. CPC G01J 5/485; C23C 16/0227; C23C 16/45536; C23C 16/45544; C23C 16/45565; C23C 16/4583; C23C 16/50; C23C 16/52; G01J 5/0066; G01J 5/0859; G01M 3/38; G06T 7/001; G06T 7/13; G01J 2005/0077; G06T 2207/10048; G06T 2207/20084; G06T 2207/30148; H04N 23/23

(57) ABSTRACT

Multi-pixel sensors such as camera sensors may be configured to capture two-dimensional and/or three-dimensional images of the interior of a process chamber or other fabrication tool. The sensors may be configured to capture pixelated electromagnetic radiation intensity information from within the interior of such process chamber before, during, and/or after processing of a substrate in the chamber. Such sensors may also be utilized for control, predictive, and/or diagnostic applications.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

High performance plasma-assisted deposition and etch processes are important to the success of many semiconductor processing workflows. However, monitoring, controlling, and/or optimizing plasma processes can be difficult and time-consuming, oftentimes involving process engineers laboriously testing process parameters to empirically determine settings that produce a target result. Additionally, many techniques for in situ monitoring of plasma processes provide only limited information, such as information at the location of VI sensors.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Certain aspects of this disclosure pertain to systems that may be characterized by the following features: (a) a device fabrication process chamber including a chamber wall and a wafer support; (b) one or more optical access apertures in the process chamber; (c) one or more camera sensors optically coupled to the one or more optical access apertures; and (d) analysis logic configured to process signals from the one or more camera sensors to determine one or more thermal characteristics of a component in the process chamber.

As examples, the optical access aperture may be a view port or window that provides a view into or on the process chamber. In some cases, the optical access aperture is an aperture specially designed for a camera sensor. In some cases, the aperture is or contains a lens or other optical element configured work with a camera sensor. In some embodiments, at least one of the one or more optical access apertures is disposed in the chamber wall and provides a generally vertical line of sight into the process chamber. In some embodiments, at least one of the one or more optical access apertures is configured to provide a generally vertical line of sight into the process chamber. As an example, the at least one of the one or more optical access apertures may be disposed in a top surface of the process chamber or in a bottom surface of the process chamber.

In certain embodiments, the process chamber includes two or more stations. In some cases, the analysis logic is configured to determine the one or more thermal characteristics of the component or a condition in a first station of the process chamber. In some cases, the component in the process chamber is in a first station of the process chamber and the analysis logic is configured to determine the one or more thermal characteristics of the component in the process chamber by accounting for an imaged feature located in a second station of the process chamber.

In some embodiments, the system additionally includes a non-camera sensor, and the analysis logic is configured to employ signals from the non-camera sensor to determine the one or more thermal characteristics of a component in the process chamber.

In certain embodiments, the one or more camera sensors include a thermal imaging camera sensor. As an example, the thermal imaging camera sensor may be a hyperspectral camera sensor. In certain embodiments, the camera sensor is configured to capture optical signals in the IR spectral region. In certain embodiments, the camera sensor is configured to capture optical signals in the UV and/or visible spectral regions and to discriminate between optical signal in (a) the IR and (b) the UV and/or visible spectral regions.

In some implementations, the camera sensor is mounted on a wafer. In some implementations, the camera sensor is disposed in an enclosure within the process chamber.

In some embodiments, the analysis logic is configured to determine the one or more thermal characteristics of the component in the process chamber, temporally. In some embodiments, the analysis logic is configured to determine the one or more thermal characteristics of the component in the process chamber in a manner that spatially resolves variations in thermal characteristics. As an example, the analysis logic is configured to (a) process images from the one or more camera sensors obtained at multiple angles, and (b) provide a three-dimensional representation of the component.

In certain embodiments, the system additionally includes one or more optical fibers and/or one or more light pipes that optically couple the one or more camera sensors to the one or more optical access apertures. In some cases, the analysis logic is configured to process multiplexed signals from at least two of the one or more camera sensors.

In certain embodiments, the component in the process chamber includes a gas supply line, a showerhead, a valve, a vent, a substrate pedestal, a substrate chuck, a coolant line, an electrode configured to provide plasma power to the process chamber, a sensor, an exhaust line, an electrical connection, an accumulator, and/or a wall of the process chamber. In certain embodiments, the component in the process chamber is a heater. As example, the heater may be connected to gas line, an accumulator volume, a vaporizer, an ampoule, an electrical connection, an exhaust line, or any combination of these.

In certain embodiments, the analysis logic is further configured to compare a current image from the camera sensor with a baseline image. For example, the analysis logic may be further configured to use a comparison of the current image and the baseline image to identify a hot spot or a cold spot on the component of the process chamber. In some implementations, the analysis logic is further configured to identify a crack, leak, and/or wear in the component based on, at least in part, the hot spot or cold spot. And, in some cases, the analysis logic is further configured to adjust a process condition and/or modify the process chamber in response to a temporal change in a comparison of the current image and the baseline image.

In certain embodiments, the analysis logic is configured to determine a temperature of a wafer in the process chamber. As an example, the temperature of the wafer may be a temperature distribution on the wafer. In some implementations, the analysis logic is configured to determine a soak time for the wafer based on the temperature of the wafer.

In certain embodiments, the analysis logic is configured to determine a flow pattern of a gas within the process chamber. As an example, the gas may be a process gas or a coolant gas. In some implementations, the analysis logic is configured to determine the flow pattern of the gas within the process chamber by determining a thermal condition of the component in the process chamber, wherein the component is in a path of the gas flow pattern. In some implementations, the analysis logic is configured to determine the flow pattern of the gas within the process chamber by determining the location of a tracer in the gas.

In certain embodiments, the signals from the one or more camera sensors include thermal images of the process chamber while it is being cleaned. In such cases, the analysis logic may be configured to characterize the process chamber undergoing cleaning and/or a condition of a cleaning operation.

In some embodiments, the analysis logic is further configured to determine one or more edges of the component in the process chamber. In some implementations, the analysis logic is configured to determine the one or more edges of the component in the process chamber by applying a noise filter to a thermal image of the component and then applying an edge finding routine to the thermal image.

In certain embodiments, the one or more thermal characteristics of the component include a nominal temperature of the component. In certain embodiments, the one or more thermal characteristics of the component include a temperature distribution of the component.

In some implementations, the analysis logic is further configured to determine, based at least partly on the thermal characteristics of the component, whether the component or a process condition in the process chamber is out of an acceptable range for continued operation without change. In some embodiments, the analysis logic is further configured to cause to be performed, based at least partly on the thermal characteristics of the component, a correcting action. In some cases, the analysis logic is further configured to compare information obtained from signals of the one or more camera sensors with a reference value and based on a magnitude of difference between the information and the reference value, determine the correcting action.

In certain embodiments, the analysis logic is further configured to monitor the one or more thermal characteristics of the component temporally, and based on a rate of change of the one or more thermal characteristics, determine that the component or the process chamber is in a fault state. In certain embodiments, the analysis logic is further configured to monitor the one or more thermal characteristics of the component temporally, and based on a rate of change of the one or more thermal characteristics, initiate or perform a correcting action for the component or process chamber.

In certain embodiments, the analysis logic is further configured to determine one or more dimensions of the component and/or one or more distances relative to the component. In some such embodiments, the analysis logic is further configured to adjust, based on the one or more dimension and/or one or more distances, a position of the component or a second component in the process chamber. In some cases, the analysis logic is further configured to adjust, based on the one or more dimension and/or one or more distances, a nominal showerhead-pedestal gap and/or a showerhead-pedestal tilt.

In certain embodiments, the analysis logic is further configured to use the one or more thermal characteristics of the component, parallax and/or foreshortening image information to determine or correct a dimension or distance in the process chamber. As an example, the dimension or distance is a measured dimension or distance in the process chamber.

Some aspects of this disclosure pertain to systems that may be characterized by the following features: (a) a process chamber including a chamber wall and a wafer support; (b) one or more optical access apertures in the chamber wall; (c) one or more camera sensors optically coupled to the one or more optical access apertures in a manner that can capture a two-dimensional image or a three-dimensional image of one or more features of a component located within the process chamber; and (d) analysis logic configured to process signals from the one or more camera sensors to (i) characterize one or more properties of the component at a first region of interest within the process chamber, and (ii) characterize the one or more properties of the component at a second region of interest within the process chamber.

In some embodiments, the analysis logic is configured to characterize the one or more properties of the component, temporally, at the two or more regions of interest within the process chamber. In some embodiments, the one or more camera sensors include at least two camera sensors located and/or oriented to capture images from at least the first region of interest and the second region of interest within the process chamber. In such embodiments, the analysis logic may be further configured to process the images from at least the first region of interest and the second region of interest to produce a spatial representation of the component in at least the first region of interest and/or the second region of interest within the process chamber.

Some aspects of this disclosure pertain to systems that may be characterized by the following features: (a) a process chamber, including a chamber wall and a wafer support; (b) an optical access aperture in the chamber wall; (c) a camera sensor optically coupled to the optical access aperture; (d) an auxiliary sensor configured to sense a thermal, optical, and/or electrical condition in the process chamber, wherein the auxiliary sensor is not a camera sensor, and (e) analysis logic configured to process signals from the camera sensor and the auxiliary sensor to characterize one or more thermal properties of a component in the process chamber.

In some embodiments, the auxiliary sensor is a voltage and/or current sensor. In some embodiments, the one or more thermal properties of the component include a temperature or an edge of the component. In some embodiments, the auxiliary sensor is a spectroscopic sensor. In some embodiments, the camera sensor includes a hyperspectral camera sensor. In some embodiments, the auxiliary sensor is an optical metrology sensor.

Some aspects of this disclosure pertain to methods that may be characterized by the following operations: (a) receiving signals from one or more camera sensors optically coupled to one or more optical access apertures of a device fabrication process chamber including a chamber wall and a wafer support; and (b) determining from the signals one or more thermal characteristics of a component in the process chamber.

In some methods, at least one of the one or more optical access apertures is disposed in the chamber wall and provides a generally vertical line of sight into the process chamber. In some methods, at least one of the one or more optical access apertures is configured to provide a generally vertical line of sight into the process chamber. For example, the at least one of the one or more optical access apertures may be disposed in a top surface of the process chamber or in a bottom surface of the process chamber.

In some embodiments, the process chamber includes at least two stations, and the component in the process chamber may be in a first station of the process chamber. In some such embodiments, determining the one or more thermal characteristics of the component in the process chamber includes accounting for an imaged feature located in a second station of the process chamber. In some embodiments, determining the one or more thermal characteristics of the component involves determining a thermal characteristic or a condition in a first station of the process chamber.

In some implementations, the method additionally includes receiving signals from a non-camera sensor on or in the device fabrication process chamber. In such implementations, determining the one or more thermal characteristics of the component in the process chamber may include using the signals from a non-camera sensor.

In various embodiments, the one or more camera sensors include a thermal imaging camera sensor. As an example, the thermal imaging camera sensor may include a hyperspectral camera sensor. In certain embodiments, the camera sensor is configured to capture optical signals in the IR spectral region. In some implementations, the camera sensor is further configured to capture optical signals in the UV and/or visible spectral regions and to discriminate between optical signal in (a) the IR and (b) the UV and/or visible spectral regions.

In certain embodiments, the camera sensor is mounted on a wafer. In certain embodiments, the camera sensor is disposed in an enclosure within the process chamber.

In some embodiments, determining the one or more thermal characteristics of the component in the process chamber involves determining the one or more thermal characteristics temporally. In certain embodiments, determining the one or more thermal characteristics of the component in the process chamber involves spatially resolving variations in thermal characteristics. In some cases, the method additional includes (i) processing images from the one or more camera sensors obtained at multiple angles, and (ii) providing a three-dimensional representation of the component.

In certain embodiments, the device fabrication process chamber additionally includes one or more optical fibers and/or one or more light pipes that optically couple the one or more camera sensors to the one or more optical access apertures. In certain embodiments, the method additional includes processing multiplexed signals from at least two of the one or more camera sensors.

In certain embodiments, the component in the process chamber includes a gas supply line, a showerhead, a valve, a vent, a substrate pedestal, a substrate chuck, a coolant line, an electrode configured to provide plasma power to the process chamber, a sensor, an exhaust line, an electrical connection, an accumulator, and/or a wall of the process chamber. In certain embodiments, the component in the process chamber is a heater. As an example, the heater may be connected to gas line, an accumulator volume, a vaporizer, an ampoule, an electrical connection, an exhaust line, or any combination of these.

In certain embodiments, the method additionally includes comparing a current image from the camera sensor with a baseline image. In some such embodiments, the method additionally includes using a comparison of the current image and the baseline image to identify a hot spot or a cold spot on the component of the process chamber. In some cases, the method also includes identifying a crack, leak, and/or wear in the component based on, at least in part, the hot spot or cold spot. In some embodiments, the method additionally includes adjusting a process condition and/or modifying the process chamber in response to a temporal change in a comparison of the current image and the baseline image.

In certain embodiments, the method additionally includes determining a temperature of a wafer in the process chamber. In some embodiments, the temperature of the wafer is a temperature distribution on the wafer. In certain embodiments, the method additionally includes determining a soak time for the wafer based on the temperature of the wafer.

In certain embodiments, the method additionally includes determining a flow pattern of a gas within the process chamber. In some implementations, the gas is a process gas or a coolant gas. In some cases, determining a flow pattern of a gas within the process chamber includes determining a thermal condition of the component in the process chamber, wherein the component is in a path of the gas flow pattern. In some cases, determining a flow pattern of a gas within the process chamber includes determining the flow pattern of the gas within the process chamber by determining the location of a tracer in the gas.

In certain embodiments, the signals from the one or more camera sensors include thermal images of the process chamber while it is being cleaned. In such embodiments, the method may further include characterizing the process chamber undergoing cleaning and/or a condition of a cleaning operation.

In certain embodiments, the method additionally includes determining one or more edges of the component in the process chamber. In certain embodiments, determining the one or more edges of the component in the process chamber is accomplished by applying a noise filter to a thermal image of the component and then applying an edge finding routine to the thermal image.

In certain embodiments, the one or more thermal characteristics of the component include a nominal temperature of the component. In certain embodiments, the one or more thermal characteristics of the component include a temperature distribution of the component.

In some embodiments, the method additionally includes determining, based at least partly on the thermal characteristics of the component, whether the component or a process condition in the process chamber is out of an acceptable range for continued operation without change. In some embodiments, the method additionally includes performing, based at least partly on the thermal characteristics of the component, a correcting action.

In certain embodiments, the method additionally includes comparing information obtained from signals of the one or more camera sensors with a reference value and, based on a magnitude of difference between the information and the reference value, determining the correcting action. In certain embodiments, the method additionally includes monitoring the one or more thermal characteristics of the component temporally, and, based on a rate of change of the one or more thermal characteristics, determining that the component or the process chamber is in a fault state. In certain embodiments, the method additionally includes monitoring the one or more thermal characteristics of the component temporally, and, based on a rate of change of the one or more thermal characteristics, initiating or performing a correcting action for the component or process chamber.

In some embodiments, the method additionally includes determining one or more dimensions of the component and/or one or more distances relative to the component. In some embodiments, the method additionally includes adjusting, based on the one or more dimension and/or one or more distances, a position of the component or a second component in the process chamber. In some embodiments, the method additionally includes adjusting, based on the one or more dimension and/or one or more distances, a nominal showerhead-pedestal gap and/or a showerhead-pedestal tilt.

In some embodiments, the method additionally includes, based on the one or more thermal characteristics of the component, parallax and/or foreshortening image information, determining or correcting a dimension or distance in the process chamber. In certain embodiments, the dimension or distance is a measured dimension or distance in the process chamber.

These and other features of the disclosure will be described in more detail below.

### BRIEF DESCRIPTION OF THE DRAWINGS

FIG. 1A schematically illustrates a fabrication tool for depositing or etching a film on or over a substrate; the tool includes a camera sensor.

FIG. 1B schematically illustrates an implementation of a multi-station processing tool; the tool includes four camera sensors.

FIG. 1C presents a top view of an electronic device fabrication system having four multi-station fabrication tools, one of which includes camera sensors.

FIG. 1D schematically depicts a process chamber with a camera oriented to capture images along a horizontal line of sight into the chamber interior.

FIG. 1E schematically depicts a process chamber with cameras oriented to capture images along vertical lines of sight into the chamber interior.

FIG. 1F depicts a process chamber having one or more camera sensors trained on areas outside the chamber walls.

FIG. 1G illustrates an embodiment in which a camera sensor is mounted to access a view port or optical access aperture of a chamber wall in a fabrication tool.

FIG. 1H presents an example of spectral sensitivity ranges for “standard” (visible-sensitive), IR-sensitive, and UV-sensitive sensor elements in a camera sensor or a combination of camera sensors.

FIG. 2 is a process flow diagram depicting an example method for detecting features in a thermal image.

FIG. 3 schematically illustrates an example control system for a fabrication tool implementing feedback, and optional feedforward control.

FIG. 4 is a flow chart illustrating singled threaded processes associated with thermal image capture and image analysis to control a process in a fabrication tool.

FIG. 5 is an example of a thermal image in accordance with some embodiments.

FIG. 6 is a diagram of an example plasma formation receptacle that may be monitored using thermal images in accordance with some embodiments.

FIG. 7 is a block diagram of an example computing environment suitable for use in implementing some embodiments of the present disclosure.

### DETAILED DESCRIPTION

### Introduction and Context

Aspects of this disclosure pertain to multi-pixel sensors such as camera sensors configured to capture images of the interior of a process chamber or other fabrication tool. The sensors may be configured to capture pixelated electromagnetic radiation intensity information from within the interior of such process chamber before, during, and/or after processing of a substrate in the chamber. Such sensors may also be utilized during nonproduction operations such as chamber cleaning operations and chamber diagnostic applications.

The electromagnetic radiation intensity that is captured by a camera sensor may arise from various sources such as thermal energy, plasmas, and/or physical (e.g., optical) probing or other stimulus of features within a process chamber.

The captured data may be in the form of radiation intensity values provided as a function of location within the process chamber. Collectively these values may form an image, such as an image of a region within the process chamber. In some embodiments, the captured intensity values are provided as a function of wavelength. In some cases, the image or other captured pixel data may be provided with color values and/or wavelength ranges. The radiation may be provided over any one or more ranges of the electromagnetic spectrum such as all or a portion of the ultraviolet, visible, and/or infrared regions. In some embodiments, the captured radiation information is obtained over a time span. In such cases, the radiation information may be captured at discrete intervals, which may correspond to a frame rate of a camera sensor. The information may be captured by sampling at a rate sufficient to capture anticipated variations in a condition within the process chamber such as pulses or other temporal variations of a light source or a plasma.

The process chamber or other fabrication tool may take any of various forms. Some examples are presented later in this disclosure. In some embodiments, the process chamber is used for fabricating an electronic device such as an integrated circuit on a semiconductor substrate. In some embodiments, the process chamber is configured to deposit one or more materials on a substrate. In some embodiments, the process chamber is configured to etch material from a substrate contained within the process chamber. In some embodiments, the process chamber is configured to deposit material and/or etch material by a thermally mediated process. In some embodiments, the process chamber is configured to deposit material and/or etch material using a plasma mediated process.

Images of a fabrication tool may be captured while the tool is active or idle. An active tool may be engaged in fabricating electronic devices or some other process such as chamber cleaning.

Some fabrication tools include a chamber having two or more stations, with each station configured to process a substrate. Thus, for example, a multi-station fabrication tool may simultaneously process two, three, four, or more substrates, in the same chamber. In some embodiments, each station in multi-station fabrication tool has its own wafer support component (e.g., a pedestal and/or wafer chuck), its own process gas delivery component (e.g., a showerhead), and/or its own plasma source (e.g., a coil or capacitor plates). The disclosure is not limited to multi-station chambers; many embodiments pertain to single station chambers.

In the context of camera sensors employed to analyze thermal signatures within a fabrication tool, a camera sensor and associated analysis logic may be configured to identify temperature profiles or other thermal signatures of components or regions of the fabrication tool. The thermal signatures may result from emission of radiation by a heated element or elements in a fabrication chamber and/or from transmission of radiation through an element or elements in the chamber. Transmitted radiation may arise from any of various sources such as thermal emissions from other heated elements and/or from plasma in the chamber. Examples of components that may provide thermal information in data captured by a camera sensor include chamber walls, gas distribution components (e.g., showerheads and/or delivery lines), substrate support components (e.g., pedestals and chucks), windows for, e.g., coupling RF energy from outside the chamber into the chamber in a regions where a plasma resides, valves, pumps, and the like.

In some cases, a camera sensor and associated analysis logic are configured to determine one or more characteristics of a gas in a region unoccupied by solid structural components of a fabrication tool. An example of such unoccupied region is a gap between a substrate support and a showerhead or other gas delivery component. Another example of such unoccupied regions is an annular region interior to a chamber wall but outside the domain of a substrate support and/or showerhead.

And in some embodiments, a camera sensor and/or associated logic may be configured to capture radiation information distributed over an area that can be divided into two or more regions of interest. The radiation information captured from the different regions of interest may be analyzed separately and/or compared.

In some embodiments, temporally varying thermal phenomena in a fabrication tool can be captured by a camera sensor, and the temporal variations analyzed. For example, a thermally cycling process may be analyzed by capturing images at different times within a process cycle (e.g., an ALD cycle) or over multiple cycles.

Analysis logic associated with the camera sensor may be configured to perform image analysis or other analysis that analyzes spatial intensity information and/or presents such information in a way that allows meaningful characterization of a fabrication tool, a process taking place in the fabrication tool, and/or a substrate being processed in a fabrication tool. The camera sensor analysis logic may be configured to receive inputs including spatially distributed radiation information, wavelength information, and/or temporal information. The logic may be configured to output images or characterizations of the radiation within a fabrication tool.

In some implementations, the logic is configured to analyze the camera sensor data to characterize a condition within a fabrication tool. Examples of such characteristics may include spatial temperature distributions, changes in temperature over time, particle formation in a chamber, gas flow patterns in a chamber, and conditions of structural features in a chamber.

In various embodiments, a camera sensor is used in conjunction with one or more non-camera sensors that capture information about the fabrication tool and/or conditions within the fabrication tool. Examples of such additional sensors include voltage/current sensors, optical emission sensors, and temperature sensors such as thermocouples, thermistors, pyrometers, bolometers, and semiconductor-based temperature sensors.

In certain embodiments, camera sensor analysis logic is configured to analyze information captured by a camera sensor in conjunction with information captured by one or more other sensors and provide characteristics of conditions within a fabrication tool such as chemical composition characteristics, process gas flow rate characteristics, plasma characteristics, tool component characteristics, and any combination thereof.

In certain embodiments, analysis logic is configured to account for a “baseline” or other prior state representation to which current information captured by a camera sensor is compared. The logic may be configured to identify differences between the current and prior state representations. The differences may be used to diagnose a condition of a fabrication tool component such as a degree of wear, a defect, or break. In some embodiments, analysis logic is configured to use information captured by a camera sensor in conjunction with information about a process and/or a fabrication tool component to determine adjustments to process parameters. Examples of information about the process or fabrication tool include recipe states, setpoints, and timing of operations in the fabrication tool.

### Terminology

Unless specified otherwise herein, all technical and scientific terms used herein have the meanings commonly understood by one of ordinary skill in the art. The terms and explanations provided immediately below are provided to aid in understanding complex concepts and to present particular embodiments. They are not intended to limit the full scope of the disclosure.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of approximately 100 mm, 150 mm, 200 mm, 300 mm, or 450 mm. This detailed description assumes the embodiments are implemented on a wafer. However, the disclosure is not so limited. The work piece may be of various shapes, sizes, and materials. Besides standard semiconductor wafers, other work pieces that may take advantage of the disclosed embodiments include various articles such as compound semiconductor wafers, printed circuit boards, magnetic recording media, magnetic recording sensors, mirrors, optical items (including optical substrates, wafers, and elements), micro-mechanical devices and the like.

Integrated circuits or other electronic devices may be fabricated on a wafer. Examples of such other electronic devices include LEDs, optical displays, tint-able devices such as photochromic and electrochromic devices, micro lens arrays, thin film batteries, and photovoltaic devices.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as an etching reactor, an electroplating cell, a chemical mechanical planarization tool, a wet etch tool, and the like. Categories of semiconductor device fabrication operations include subtractive processes, such as etch processes and planarization processes; and material additive processes, such as deposition processes (e.g., physical vapor deposition, chemical vapor deposition, atomic layer deposition, electrochemical deposition, and electroless deposition). In the context of etch processes, a substrate etch process includes processes that etch a mask layer or, more generally, processes that etch any layer of material previously deposited on and/or otherwise residing on a substrate surface. Such etch process may etch a stack of layers in the substrate.

“Manufacturing equipment” or “fabrication tool” refers to equipment in which a manufacturing process takes place. Manufacturing equipment may include a processing chamber in which the workpiece resides during processing. Typically, when in use, manufacturing equipment performs one or more electronic device fabrication operations. Examples of manufacturing equipment for semiconductor device fabrication include subtractive process reactors and additive process reactors. Examples of subtractive process reactors include dry etch reactors (e.g., chemical and/or physical etch reactors), wet etch reactors, and ashers. Examples of additive process reactors include chemical vapor deposition reactors, and atomic layer deposition reactors, physical vapor deposition reactors, wet chemical deposition reactors, electroless metal deposition cells, and electroplating cells.

In various embodiments, a process reactor or other manufacturing equipment includes a tool for holding a substrate during processing. Such tool is often a pedestal or chuck, and these terms are sometimes used herein as a shorthand for referring to all types of substrate holding or supporting tools that are included in manufacturing equipment.

As used herein and unless otherwise qualified, the term camera sensor is not limited to sensors designed or configured to work with a camera. The term includes other multi-pixel radiation sensors, with or without color or multispectral filters, that can provide sensed information that can provide an image of a radiation distribution within a fabrication tool.

The term “image” refers to a spatial representation of a physical domain including one or more features. An image may be provided in the form of data or signals arranged to represent the physical domain. An image may be produced by a pixelated sensor such as a camera sensor. An image may contain the spatial representation of the physical domain in one dimension, two dimensions, or three dimensions. Multiple images obtained consecutively over time may form a video representation of the physical domain.

A region of interest is a bounded region in two-dimensions or three-dimensions within a field of view of one or more camera sensors. In various embodiments, a region of interest includes a region within a fabrication tool. A region of interest may include or encompass an area or volume where a hardware component or a portion of such component exists within a fabrication tool. A region of interest may include or encompass an area or volume where a void exists such as a gap between a showerhead and a pedestal. In some cases, a boundary of a region of interest has a vertical dimension within a fabrication tool, e.g., along an axis perpendicular to the main flat surface of a wafer support (e.g., pedestal) and/or a chamber showerhead. In some cases, a boundary of a region of interest has a horizontal dimension within a fabrication tool, e.g., along an axis parallel to the main flat surface of a wafer support (e.g., pedestal) and/or a chamber showerhead. In some cases, a boundary of a region of interest has an azimuthal dimension within a fabrication tool, e.g., an angular position along a circumferential portion of a substrate/wafer, showerhead, or pedestal.

Information Collected with a Camera Sensor

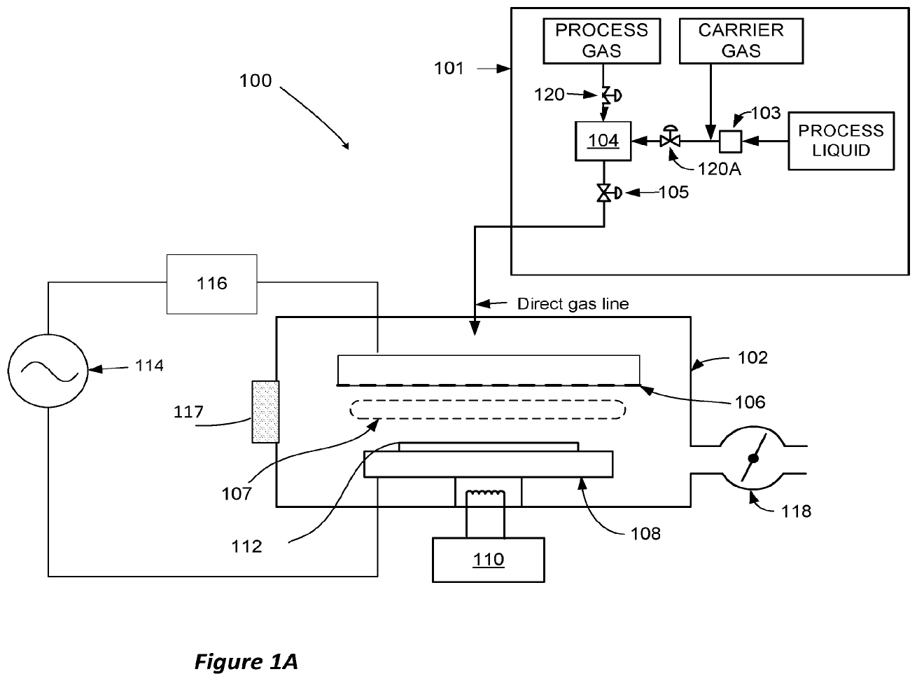

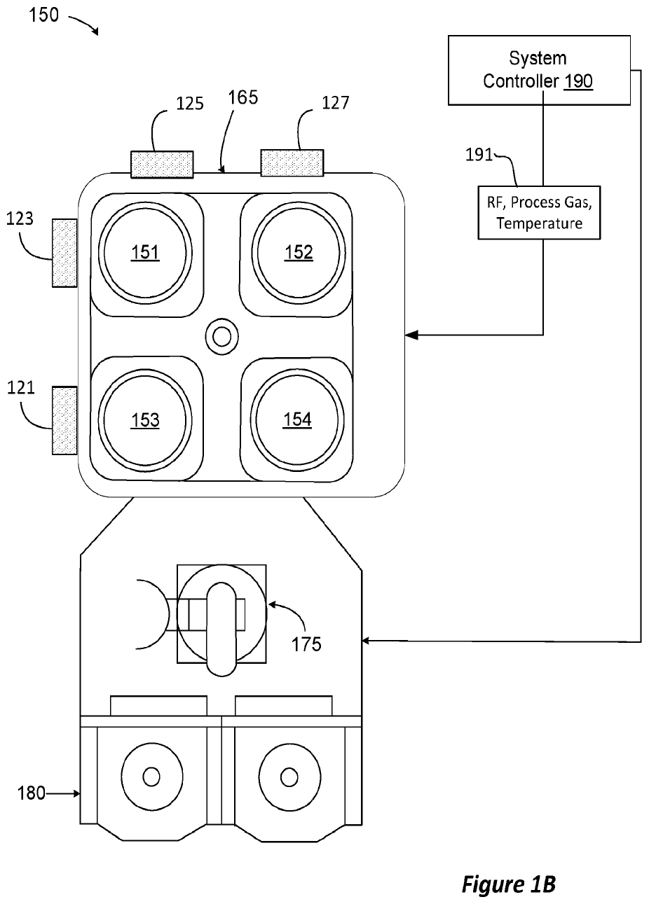

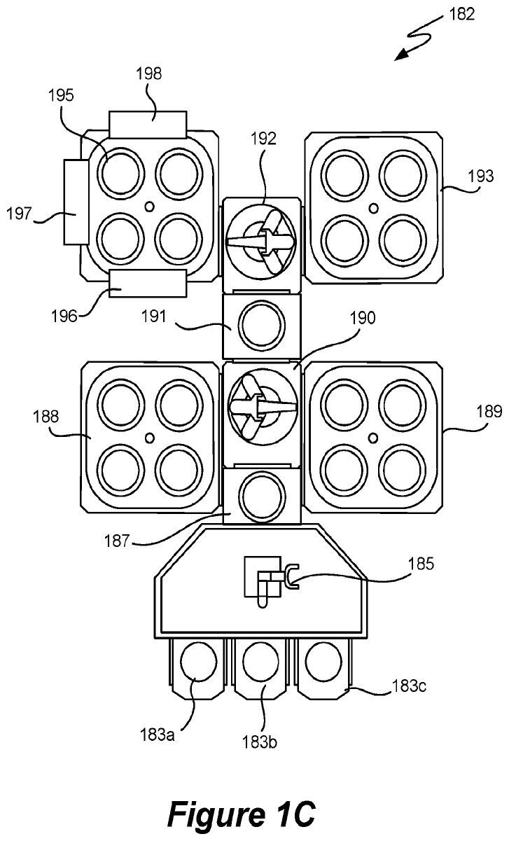

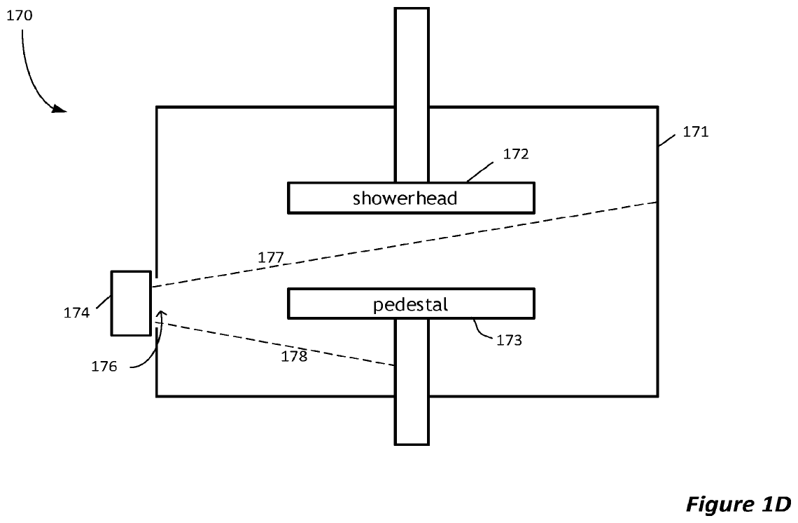

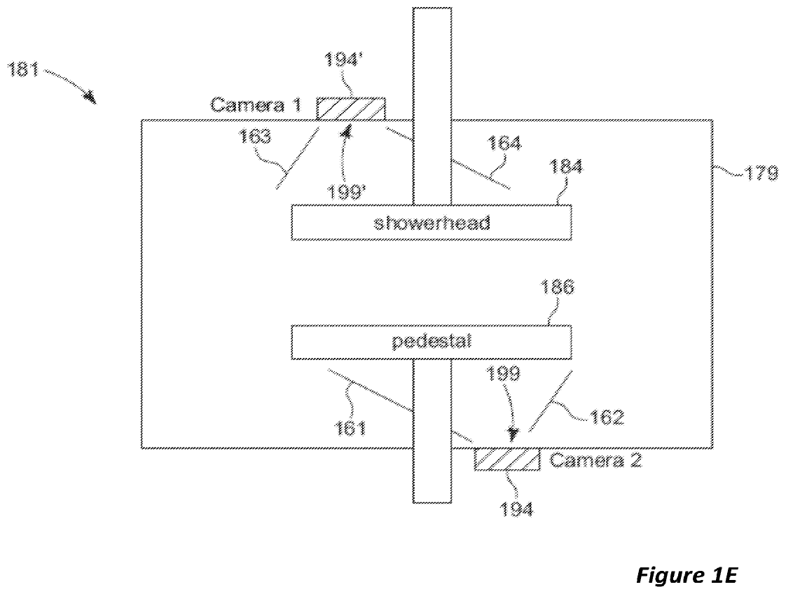

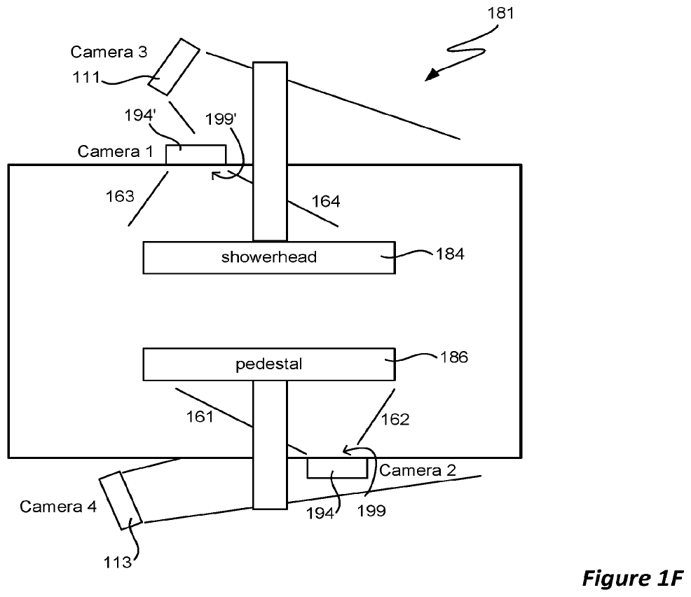

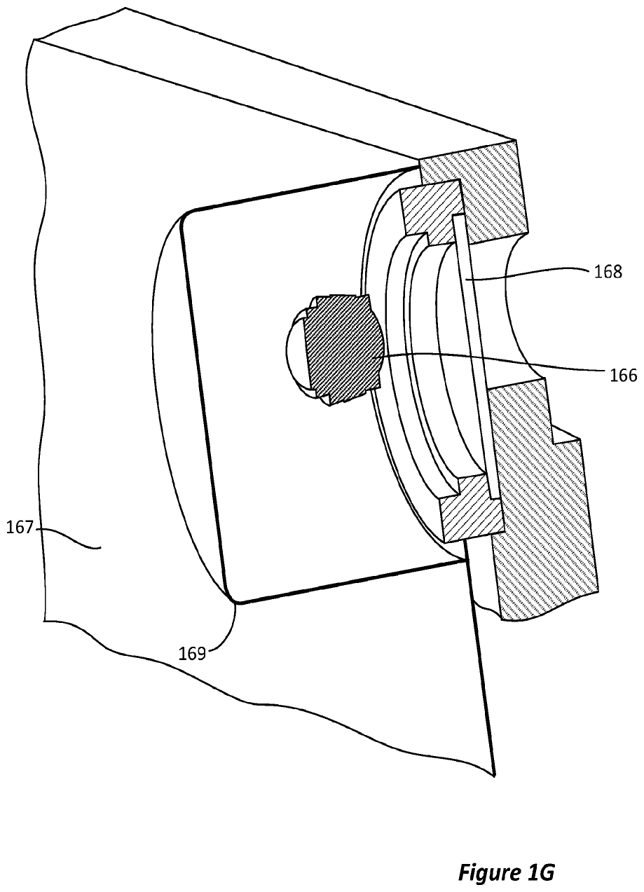

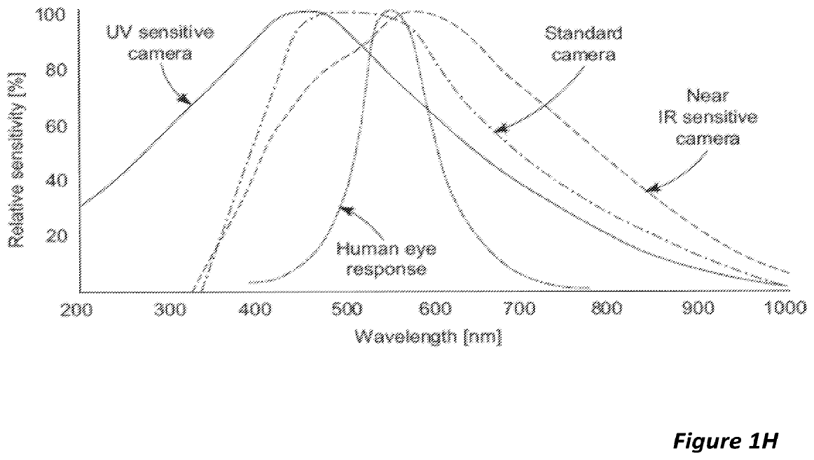

Information about conditions within a process chamber, as captured with a camera sensor or pixelated sensor, may include radiation intensity values as a function of position within the process chamber and/or a component within the process chamber. In some embodiments, the radiation intensity values are provided as an image. In some embodiments, the radiation intensity values are provided as two-dimensional or three-dimensional pixelated values. In other embodiments, the radiation intensity values are provided in only one dimension such as along a slit or interface between components. Optionally, the intensity values are also provided as a function wavelength. In some embodiments, a camera sensor or other pixelated sensor includes separate detection elements, each configured to capture radiation values at a given location, but with different spectral sensitivity profiles; e.g., in the red, green, and blue regions. In some embodiments, a camera sensor is configured or used to capture thermal signatures is configured to detect radiation in the infrared portion of the EM spectrum. Some camera sensors are configured to capture radiation intensity values in discrete wavelength ranges that are sometimes referred to as bins. Such sensors include hyperspectral imagers that capture intensity values in narrow wavelength bins and multispectral imagers that capture intensity values over broader wavelength bins. FIG. 1H presents an example of spectral sensitivity ranges for “standard” (visible-sensitive), IR-sensitive, and UV-sensitive sensor elements in a camera sensor or a combination of camera sensors. Optionally, the intensity values are provided as function or time; for example, images may be captured as video frames. In some embodiments, multiple camera sensors provide information from different overlapping or contiguous regions within a fabrication tool.

### Thermal Characteristics Determined Using a Camera

One or more camera sensors and associated analysis logic may be configured to provide any of various characteristics of components and/or conditions in a fabrication tool. Among the types of tool and/or process characteristics that may be determined are local and/or distributed temperature values within the tool. Absolute and/or relative temperature values may be determined. Temperature values may be relative to values at other locations in an image or reactor or to values captured at other times. The temperature distribution may be determined in one-dimension, two-dimensions, or three dimensions (optionally involving input from multiple camera sensors). In some implementations, analysis logic may be configured to detect defects from unexpected discontinuities in a temperature distribution or from other indicia reflecting a deviation in thermal conductivity or emission. Thermal emission from a tool component (or a portion thereof) may be determined by, e.g., IR intensity distributions obtained by a camera sensor. Alternatively, or in addition, radiation transmissivity of a tool component and/or workpiece (e.g., a semiconductor substrate) may be determined in IR and/or visible images of the component or workpiece by a camera sensor. Signatures of chemical species within the tool may be determined from IR and/or visible images of regions with a tool.

In some embodiments, logic for analyzing information sensed by a camera sensor is configured to determine and optionally present a location of components and/or sources of thermal energy within a fabrication tool. Such location may be provided with reference to one or more structural components within a fabrication tool. Examples of such components include a substrate, such as a substrate undergoing a fabrication process, a substrate support, a showerhead, and a process chamber wall. In some embodiments, the component location is determined in two or three dimensions radially, azimuthally, and/or vertically with respect to a reference such as geometric coordinates with respect to an origin, which may correspond to a location within or proximate a fabrication tool.

The boundary of a component may be determined by, e.g., a spatial intensity magnitude threshold, an intensity gradient, etc. In certain embodiments, analysis logic is configured to use the shape or boundary location of a component or source of thermal energy to identify one or more anomalies within a fabrication tool. In some cases, a plasma is bounded by a plasma sheath adjacent to one or more electrodes.

In some embodiments, the analysis logic is configured to determine a relative temperature distribution or EM spectral intensity distribution of a component or region in a fabrication tool with respect to a baseline temperature distribution or spectral intensity distribution. For example, the logic may be configured to interpret camera sensed data to determine and compare a temperature distribution in a “golden” process to sensed information in other runs or process recipes and determine a drift or shift in temperature. This may be employed in validation of runs or processes.

In various embodiments, the camera sensor analysis logic is configured to identify and optionally characterize temperature and/or IR intensity variations in one or more components or regions of a fabrication tool over time. Comparing a current temperature or intensity condition, as determined from a camera image, to a baseline condition may be employed to detect, for example, anomalies, which may in turn trigger corrections in the process parameters or maintenance after the run completes. The logic may be configured to identify and/or characterize time-based variations in a temperature or intensity as a function of position within a fabrication tool. For example, the logic may be configured to characterize time-based variations in different regions of interest in a fabrication tool.

In some embodiments, the logic is configured to characterize temperature or plasma pulses over a range of time. In some embodiments, the logic is configured to characterize such pulses at two or more regions of interest in a fabrication tool.

In some embodiments, logic for analyzing information sensed by a camera sensor is configured to determine the presence of, and optionally the concentration of, one or more chemical species within a fabrication tool. The analysis logic may be configured to determine and optionally present chemical composition information at one or more positions within a fabrication tool. In some cases, the analysis logic is configured to provide images of the composition distribution of one or more chemical species within a fabrication tool. Examples of chemical species that may be characterized by the analysis logic include unexcited or ground state species, excited species (e.g., radicals), and/or ionic species. Composition information, and in some cases, concentrations of components may be determined using spectral distribution of radiation intensity information sensed by the elements of a camera sensor. The intensity information may be provided in Red/Green/Blue bands of a conventional camera sensor or in four more spectral bands of a hyperspectral sensor.

In some cases, analysis logic is configured to use spectral details from the camera alone to provide information about chemical composition. In some cases, analysis logic is configured to use spectral details from the camera in combination with other wavelength specific signals such as those from a point location such as spectroscopy signals (e.g., OES)) to provide information about chemical composition. In some embodiments, a system employs a multi-spectral camera, a hyperspectral camera, a spectrometer, or some combination thereof to capture information from a fabrication tool that associated logic uses to characterize the chemical composition of one or more components in a fabrication tool. In some implementation, a system is configured with one or more wavelength-specific filters configured to pass only radiation associated with one or more chemical or atomic species of interest. Intensity readings in spectral regions for such species may be interpreted to determine the presence or absence of the species and/or their composition(s).

In some cases, a fabrication tool includes one or more multi-spectral or hyperspectral cameras with one or more color filters that target IR light bands common in certain processes. Examples of such bands correspond to emission or absorption spectra of tool components, coatings on such components, reactants, or other items that exist in fabrication tools. While some camera sensors can detect IR light, unless color filters are applied at the sub-pixel level (as may be the case with multi-spectral or hyperspectral cameras), such sensors cannot distinguish between different emission lines of gases in the fabrication tool. Analysis logic may be configured to compare the intensities of emissions at a few key wavelengths (where light passes between filtered regions) over time. The logic may be further configured to use such comparison to provide feedback regarding the chemistry within a tool.

In some applications, component gases are flowed individually into a fabrication tool, and wavelength-specific camera images are provided as baseline or calibration images to elucidate chemical composition information from images having multiple chemical components. Camera images may be employed to capture flow patterns of various chemical species within a reactor (e.g., from showerhead to pedestal or wafer).

### Location and Integration a Camera in a Plasma Fabrication Tool

A fabrication tool such as a process chamber may have one or more features that can be thermally imaged to allow monitoring of the tool, monitoring of a process being performed in the tool, process control, diagnosis of a condition of a component in the tool, tool maintenance, or other function. The number, position, and orientation of camera sensors on or near the tool determine which features are imaged and which functions are performed.

In some cases, a plasma provides thermal energy to certain regions or components of a tool and therefore influences the thermal conditions of those regions or components. In some cases, a process gas flow which may deliver thermal energy to or remove thermal energy from one or more regions or components of a tool and therefore influences the thermal conditions of those regions or components. Chemical reactions, which may be exothermic or endothermic, provide or remove heat from one or more components or regions of a tool and therefore influence the thermal conditions of those regions or components. Active cooling components configured for active thermal management of one or more regions or components of a tool influence the thermal conditions of those regions or components.

By strategically positioning one or more camera sensors on or near a fabrication tool, the sensors and associated analysis logic may capture thermal signatures of the one or more components or regions of a fabrication tool. Those signatures may reflect thermal energy transfer resulting from plasma generation, gas flow, chemical reactions, active cooling, or other mechanism. Using such thermal signatures, the analysis logic may facilitate monitoring, controlling, adjusting, servicing, and the like. As explained in some of the examples below, the location and orientation of a camera sensor determines the direction and path of a camera sensor's line of sight, and hence the components, features, and/or regions of the tool for which thermal images may be captured. The line of sight may be oriented substantially vertically, substantially horizontally, obliquely, or in some other direction with respect to the tool's frame of reference. Camera sensors may be positioned to capture thermal images of the interior and/or exterior of a fabrication tool. Camera sensors may be positioned within a tool's chamber, on the exterior of a chamber, on an ancillary structure such as a wafer handling robot, a load lock, a dedicated wafer, or elsewhere. FIGS. 1A-H present a few examples of process chambers and associated camera sensors.

FIG. 1A shows a fabrication tool denoted as substrate processing apparatus 100. Apparatus 100 may be configured for depositing films on or over a semiconductor substrate utilizing any number of processes. For example, apparatus 100 may be adapted for performing, in particular, chemical vapor deposition (CVD) atomic layer deposition (ALD), or atomic layer etching. Any of these processes may be performed with or without plasma excitation. Apparatus 100 includes a camera or camera sensor 117 on a chamber wall. Camera sensor 117 is configured to capture image data from the interior of apparatus 100.

Processing apparatus 100 of FIG. 1A may employ a single process station 102 of a process chamber with a single substrate holder 108 (e.g., a pedestal) in an interior volume, which may be maintained under vacuum by a vacuum pump 118. A showerhead 106 and a gas delivery system 101, which are fluidically coupled to the process chamber, may permit the delivery of film precursors, for example, as well as carrier and/or purge and/or process gases, secondary reactants, etc.

In FIG. 1A, gas delivery system 101 includes a mixing vessel 104 for blending and/or conditioning process gases for delivery to showerhead 106. One or more mixing vessel inlet valves 120 may control introduction of process gases to mixing vessel 104. Particular reactants may be stored in liquid form prior to vaporization and subsequent delivery to process station 102 of a process chamber. The implementation of FIG. 1A includes a vaporization point 103 for vaporizing liquid reactant to be supplied to mixing vessel 104. In some implementations, vaporization point 103 may include a heated liquid injection module. In some other implementations, vaporization point 103 may include a heated vaporizer. In yet other implementations, vaporization point 103 may be eliminated from the process station. In some implementations, a liquid flow controller upstream of vaporization point 103 may be provided for controlling a mass flow of liquid for vaporization and delivery to process station 102.

Showerhead 106 may operate to distribute process gases and/or reactants (e.g., film precursors) toward substrate 112 at the process station, the flow of which may be controlled by one or more valves upstream from the showerhead (e.g., valves 120, 120A, 105). In the implementation depicted in FIG. 1A, substrate 112 is depicted as located beneath showerhead 106, and is shown resting on a pedestal 108. Showerhead 106 may include any suitable shape and may include any suitable number and arrangement of ports for distributing process gases to substrate 112. In some implementations involving 2 or more stations, gas delivery system 101 includes valves or other flow control structures upstream from the showerhead, which can independently control the flow of process gases and/or reactants to each station so as to permit gas flow to one station while prohibiting gas flow to a second station. Furthermore, gas delivery system 101 may be configured to independently control process gases and/or reactants delivered to each station in a multi-station apparatus such that the gas composition provided to different stations is different; e.g., the partial pressure of a gas component may vary between stations at the same time.

In the implementation of Figure TA, gas volume 107 is depicted as being located beneath showerhead 106. In some implementations, pedestal 108 may be raised or lowered to expose substrate 112 to gas volume 107 and/or to vary the size of gas volume 107. The separation between pedestal 108 and showerhead 106 is sometimes referred to as a “gap.” Optionally, pedestal 108 may be lowered and/or raised during portions of the deposition process to modulate process pressure, reactant concentration, etc., within gas volume 107. Showerhead 106 and pedestal 108 are depicted as being electrically coupled to RF signal generator 114 and matching network 116 for coupling power to a plasma generator. Thus, showerhead 106 may function as an electrode for coupling radio frequency power into process station 102. RF signal generator 114 and matching network 116 may be operated at any suitable RF power level, which may operate to form plasma having a desired composition of radical species, ions, and electrons. In addition, RF signal generator 114 may provide RF power having more than one frequency component, such as a low-frequency component (e.g., less than about 2 MHz) as well as a high frequency component (e.g., greater than about 2 MHz). In some implementations, plasma ignition and maintenance conditions are controlled with appropriate hardware and/or appropriate machine-readable instructions in a system controller which may provide control instructions via a sequence of input/output control instructions. In some embodiments, such as those requiring only thermal driving forces for reaction, the system does not include plasma generation components.

In general, any fabrication tool may be used to implement the disclosed embodiments, including integration of a camera sensor configured to capture images thermal phenomena within a fabrication tool. Example deposition apparatuses include, but are not limited to, apparatus from the ALTUS® product family, the VECTOR® product family, and/or the SPEED® product family, the KIYO® product family, the STRIKER® product family, and the VERSYS® product family, each available from Lam Research Corp., of Fremont, California.

For simplicity, processing apparatus 100 is depicted in FIG. 1A as a standalone station (102) of a process chamber for maintaining a low-pressure environment. However, some fabrication tools employ a plurality of process stations such as shown in FIG. 1B, which schematically depicts an implementation of a multi-station fabrication tool 105. Fabrication tool 150 employs a process chamber 165 that includes multiple fabrication process stations, each of which may be used to perform processing operations on a substrate held in a wafer holder, such as pedestal 108 of FIG. 1A, at a particular process station. In the implementation of FIG. 1B, the process chamber 165 is shown as having four process stations 151, 152, 153, and 154. However, in certain other implementations, multi-station processing apparatuses may have more or fewer process stations depending on the implementation and, for instance, the desired level of parallel wafer processing, size/space constraints, cost constraints, etc. FIG. 1B additionally shows substrate handler robot 175, which may operate under the control of system controller 190, configured to move substrates from a wafer cassette (not shown in FIG. 1B) from loading port 180 and into multi-station process chamber 165, and onto one of process stations 151, 152, 153, and 154.

As depicted, process station 153 has an associated camera or camera sensor 121 located and configured to obtain images from within process station 153 and, in some embodiments, from within process chamber 154. Process station 151 has two associated cameras or camera sensors 123 and 124. Camera sensor 123 is located and configured to obtain images from within process station 151 and, in some embodiments, from within process chamber 152. Camera sensor 125 is located and configured to obtain images from within process station 151 and, in some embodiments, from within process chamber 153. Process station 152 has an associated camera or camera sensor 127 located and configured to obtain images from within process station 152 and, in some embodiments, from within process chamber 154. Any one or more of camera sensors 121, 123, 125, and 127 may be optically coupled to the interior of process chamber 165 via view port, window, or other optical access aperture disposed in or on the chamber such as in the chamber wall. It should be understood that FIGS. 1A, 1B, and other system/apparatus figures herein merely present examples showing the number and location of camera sensors. Any number of camera sensors may be employed for a fabrication tool, and these sensors may be located at any of various positions in or around the tool and its chamber wall. For example, one or more cameras may be used at any given station. Further, a given camera sensor may be positioned and oriented to “look” at other stations other than the one it is most directly associated with (within line of sight). A chamber wall may include a substantially vertically aligned peripheral portion and/or a top portion and/or a bottom portion. A window or optical aperture may be placed in any one or more such portions. A camera sensor associated with any window or aperture may have a substantially vertical line of sight (e.g., it is substantially parallel to a vertical portion of a chamber wall), a substantially horizontal line of sight (e.g., it is substantially parallel to top and/or bottom portion of a chamber wall), or an oblique line of sight.

Fabrication tool 150 includes a system controller 190 configured to control process conditions and hardware states of process tool 150. It may interact with one or more sensors, gas flow subsystems, temperature subsystems, and/or plasma subsystems—collectively represented as block 191—to control process gas flow, thermal conditions, and plasma conditions as appropriate for controlling a fabrication process. System controller 190 and subsystems 191 may act to implement a recipe or other process conditions in the stations of process chamber 165.

In multi-station fabrication tools, an RF signal generator may be coupled to an RF signal distribution unit, which is configured to divide the power of the input signal into, for example, four output signals. Output signals from an RF signal distribution unit may possess similar levels of RF voltage and RF current, which may be conveyed to individual stations of a multi-station fabrication tool.

FIG. 1C provides a top view of an electronic device fabrication system 182 having four quad-station fabrication tools 188, 189, 193, and 195. Each quad-station tool contains four process stations, each configured to hold and process a substrate. At the front end of system 182 are three FOUPs 183a, 183b, and 183c accessible by a front-end wafer handling robot 185, which is configured to transfer wafers between the FOUPs and a load lock 187. A first wafer handler 190 is located and configured to transfer wafers between load lock 187 and quad-station fabrication tools 188 and 189. Wafer handler 190 is also configured to transfer wafers to second load lock 191 which makes wafer available to quad-station fabrication tools 193 and 195 via a second wafer handler 192.

Quad-station tool 195 includes three cameras 196, 197, and 198 disposed around its outer wall. The cameras are shown vertically affixed to three sides of the four-sided chamber of tool 195. The only side without a camera is the side next to the wafer handler 192. While not shown in FIG. 1C, similar camera arrangements can be provided on any one or more of each of the three other quad station chambers in the system.

Alternatives to the arrangements shown in Figures TA-C include (a) cameras on corners of chambers (not necessarily on flat walls) and/or (b) light pipes (rigid or flexible) or optical fibers disposed within the reactor (e.g., between one or more optical access aperture in a chamber wall and one or more locations within a chamber interior). Additionally, a camera sensor's location and orientation may provide a horizontally oriented line of sight (with respect to an operating fabrication tool's frame of reference), a vertically oriented line of sight, or an intermediate line of sight (along an axis having an angle between horizontal and vertical). In some embodiments, an optical access aperture for a camera sensor is located on vertical side or chamber wall of a fabrication tool. In some embodiments, a viewport or other window for a camera sensor is located on the top or bottom of a fabrication tool. Further, it should be understood that systems employing one, two, or more cameras are not limited to quad-station chambers or even multi-station chambers. It should be understood that, in some embodiments, a camera may not be limited to viewing inside or through a viewport. For example, a camera may be oriented and/or configured to acquire images of one or more components disposed outside of the main station or chamber volume. By way of example, a camera may be used to acquire thermal images of one or more heaters outside of the main station or chamber volume.

FIGS. 1D and 1E schematically illustrate fabrication tools with camera sensors oriented to capture images from a horizontally directed and a vertically directed line of sight, respectively. FIG. 1D shows a process chamber 170 having a chamber wall 171, a showerhead 172, and a pedestal 173, all designed and constructed in any manner that is known in the art. FIG. 1D also includes a camera 174 arranged to capture images of the interior of process chamber 170 via a view port (as provided on conventional fabrication tools) or a window 176 designed for camera access (e.g., a 1-10 mm diameter sapphire rod). Camera 174 has a field of view defined by edges 177 and 178. As illustrated camera 174 and window 176 are arranged to allow the camera to capture thermal images including the vertical edge of pedestal 173. Other arranges permit the camera to capture thermal images of other vertical edges in the process chamber.

FIG. 1E shows a similar process chamber 181 but with a camera having a vertical line of sight to allow capture of thermal images of other features. Specifically, chamber 181 has a chamber wall 179, a showerhead 184, and a pedestal 186, all designed and constructed in any manner that is known in the art. FIG. 1E also includes vertically oriented cameras 194 and 194′ arranged to capture images of the interior of process chamber 181 via view ports or windows 199 and 199′ designed for camera access. Camera 194 has a field of view defined by edges 161 and 162, while camera 194′ has a field of view defined by edges 163 and 164. As illustrated camera 194 and window 199 are arranged to allow the camera to capture thermal images including a stem or lower side of pedestal 186. As illustrated camera 194′ and window 199′ are arranged to allow the camera to capture thermal images including an edge of a stem and/or backside of showerhead 184. Other arrangements permit the camera to capture thermal images of other edges in the process chamber.

FIG. 1F presents a variation of the design depicted in FIG. 1E. Because some useful thermal information may present on the outside of chamber, one or more camera sensors may be trained on areas outside the chamber walls. In the example of FIG. 1F, process chamber 181 additionally includes a camera sensor 111 trained on a portion of the exterior of an upper chamber wall and a camera sensor 113 trained on a portion of the exterior of a lower chamber wall. Note that exterior trained camera sensors may be used alone or in conjunction with interior trained sensors as depicted in FIG. 1F (e.g., sensors having a horizontal or vertical line of sight).

A camera sensor is typically disposed outside of a fabrication tool, although in some embodiments, it is integrated with a chamber wall or other component or assembly within the chamber. In certain embodiments, a window specially constructed for a camera sensor is integrated into a chamber wall. In certain embodiments, a camera sensor is optically coupled to an interior of a fabrication tool using an optical access aperture that is provided in or on a chamber wall to allow visual inspection of the tool interior.

FIG. 1G illustrates an arrangement for attaching a camera to the wall of a fabrication tool. The view is from the inside of a chamber, which is shown in cross-section. As shown, a camera 166 attached to a wall of a process chamber 167. Camera 166 is configured and oriented to capture images of the interior of process chamber 167 via a view port 168. Camera 166 is disposed in a protective enclosure 169 also attached process chamber wall 167.

A view port or other window for allowing a camera sensor to “view” a chamber interior may be made from any of a variety of materials. Examples include UV fused silica, UV fused quartz, sapphire, borosilicate glass, and calcium fluoride. In other embodiments, laminates or composites of multiple materials may be utilized in fabricating the windows. In certain embodiments, a window is substantially transmissive over a spectral range of about 100-6000 nm or about 100-1000 nm. To make such a wide spectral range usefully available to a camera, a commercial sensor may need to be modified by removing one or more wavelength-specific or wavelength range-limiting filters on the sensor as manufactured or sold.

An optical access aperture, which may be, for example, a view port or other window, for allowing a camera sensor to view a chamber interior may have any of various sizes and shapes. In certain embodiments, a window has a circular, elliptical, or polygonal shape. In some embodiments, a window in a chamber wall is constructed as an optical element such as a mirror, lens, filter, polarizer, or grating. In some embodiments, a window is integrated with a mirror. Some embodiments further may include optical mirrors or other optical components not integrated with the window but rather located within the chamber to, e.g., enable optical access to regions of the chamber that do not have line-of-sight to an optical access aperture. In certain embodiments, the window is a cylindrical piece of sapphire. In certain embodiments, the window may be coated with one or more antireflective films.

View ports have been observed to produce thermal and electrical anomalies. Therefore, eliminating view ports and replacing them with small dimension windows or other optical access aperture may provide benefits to the fabrication tool processing environment. In certain embodiments, a window has a maximum cross-sectional dimension (e.g. a diameter or diagonal) of about 5 cm or less, or about 5 mm or less.

In certain embodiments, a fabrication tool or a station in a fabrication tool is outfitted with more than one camera. In some cases, a fabrication tool or station has 3 or more cameras, or 5 or more cameras, or 8 or more cameras, or 10 or more cameras. In some embodiments, a station of a multi-station tool has 1 to 3 camera sensors.

The individual camera sensors of a multi-sensor tool or station may be positioned and configured to capture different fields of view within the tool or station interior. In some implementations, different cameras are located and oriented to capture images of the tool interior at different angles. In some implementations, different cameras are located and oriented to capture images of the tool interior at different translational offsets. In some embodiments, camera sensor analysis logic is configured to stitch or otherwise combine images from two or more individual camera sensors located and oriented to capture different regions and/or angles within a tool interior.

In embodiments employing multi-chamber fabrication tools, one or more camera sensors are located and oriented to capture information about two or more chambers. This may be convenient when two or more stations are along a line of sight from an optical access aperture outfitted with a camera sensor. In some implementations, camera sensor analysis logic is configured to use information about structural features of adjacent stations such as station walls, or showerheads, or pedestals, to provide context or frame of reference for plasma radiation data collected from a different station.

In some embodiments, a camera sensor is directly attached to a wall or window of a fabrication tool. A camera sensor may be affixed to a fabrication tool by various mechanisms such as an adhesive, a bolt or other mechanical fixture, a magnet, etc. In some embodiments, a camera sensor is disposed at a remote location from a fabrication tool. For example, a camera sensor may be optically coupled to an optical access aperture via a fiber or other light conduit. Some embodiments allow for camera mounted in a protective enclosure within a fabrication tool interior. In some embodiments, a camera sensor is attached to an ancillary structure exterior to the fabrication tool. For example, a sensor may be attached a wafer handling component such as a robot. As another example, a sensor may be attached to a test or sensing wafer that moves from outside the tool to inside the tool, where it may optionally experience fabrication conditions and collect images during this process.

One or more camera sensors may be arranged to provide a multiplexed processing of images. In some embodiments, a single remote sensor may process optical information (and generate images) from multiple locations (e.g., multiple optical access apertures). For example, a single camera sensor may support multiple optical access apertures. In some embodiments, a fabrication tool employs one camera sensor to capture image data from two more stations of a multi-station chamber. For example, a tool may have a first window on a chamber wall adjacent a first station and a second window on the chamber wall adjacent a second station. The tool additionally includes a first optical fiber or light pipe optically coupling the first window to a camera sensor and a second optical fiber or light pipe optically coupling the second window to the same camera sensor. The camera sensor is configured to multiplex or concurrent process signals from the first and second optical fibers or light pipes. In some embodiments, the tool includes an array of light pipes and/or an array of optical fibers for conveying optical signals between a source in the tool and a camera sensor.

In some implementations, a system includes two or more multiprocessing or multiplexing units, each configured to process camera sensor data within a different domain, e.g., within different spectral ranges. For example, one unit may be configured to process visible light from one or more sensors and a second unit may be configured to process thermal signals (e.g., IR radiation) from one or more sensors. The two units may be configured to work synchronously, capturing and/or processing different types of information. As an example, the two multiprocessing units may collectively provide combined images of a region or component, with one part showing a temperature distribution of the region or components and another part showing a filtered plasma image showing dominance of a particular species in the region or component. As another example, two multiprocessing units may be configured to operate asynchronously to capture information separated by some delay.

### Characteristics of Cameras for Sensing Thermal Conditions

Camera sensors are characterized by various parameters including the number of pixels, range of wavelengths captured, and the like. In some embodiments, a camera sensor for capturing information about a plasma may be capable of sensing intensity values of electromagnetic radiation at wavelengths including at least portion of the UV spectrum, at least a portion of the visible spectrum, at least a portion of the IR spectrum, or any combination thereof. As an example, a camera sensor may be configured to sense intensity values over range including 100 nm to 1000 nm. For some thermal imaging applications, a camera sensor is configured to sense radiation in at least a portion of the IR region and/or in at least a portion of the visible region and at least a portion of the IR region. In various embodiments, a camera sensor configured for thermal imaging may sense radiation in a range including about least about 900 to 13,000 nm. FIG. 1H presents spectral sensitivity ranges for various camera sensor types, including sensors tuned for near IR sensitivity.

In certain embodiments, the camera sensor is a thermal imaging camera sensor. Such cameras may produce signals having at least one feature that correlates with the temperature of a region in the thermal camera's field of vision. In some embodiments, a thermal imaging camera is sensitive to radiation within at least a portion of the IR spectral region, with different subranges corresponding to different temperatures of an object in a pixelated image captured with the camera. A thermal imaging camera is also sometimes referred to as a thermographic camera, an infrared camera or thermal imaging camera or thermal imager.

As examples for any embodiments herein, camera sensors may be constructed as charge-coupled devices (CCDs) or CMOS arrays. In certain embodiments, a camera sensor as used herein has at least about 5 megapixels or at least about 12 megapixels.

In certain embodiments, a camera as used in any of the embodiments herein is configured with a shutter. In some implementations, a camera is configured to capture video data of a plasma in a fabrication tool. In certain embodiments, a camera is configured to capture video information of a plasma in a fabrication tool at a frame rate of about 30 fps-120 fps.

In some cases, a fabrication tool may include a lighting system configured to illuminate all or one or more portions of the too interior. In some implementation, a lighting system is configured to allow a camera to take an illuminated image when the plasma is off (e.g., outside operation, or in between pulses). In some implementations, a lighting system employs one or more LEDs or other light sources. The light sources may be monochromatic, polychromatic with discrete emission wavelengths, or broad spectrum. The light source may be active continuously, pulsed synchronously with one or more camera shutters, pulsed asynchronously with one or more camera shutters, or pulsed synchronously with other process parameters such as RF generators or gas delivery valves. In other implementations, multiple light sources are employed in different locations within or outside the chamber. These multiple light sources can be energized continuously or sequentially with timing managed to enable structured lighting to be utilized to construct super-resolution images of features within the chamber.

Some fabrication tools include a still image or video display. Such display may be employed to allow staff to view the too interior when a camera sensor or light conduit blocks access to a view port from outside the tool.

Other Sensor Types that May be Used in Conjunction with Cameras

In some embodiments, a fabrication tool includes one or more sensors in addition to a camera sensor. Such additional sensor(s) may be configured to sense a plasma or other conditions in situ. Such sensors may include, but are not limited to, mechanical limit sensors, inertial sensors (e.g., accelerometers or gyroscopes), infrared (IR) sensors, acoustic sensors, mass flow sensors, pressure sensors such as the pressure manometers, and temperature sensors such as thermocouples, which may be located in a process gas delivery system, a pedestal, a chuck, etc. Some sensors may be configured to provide information about only a single point or small region compared to a camera sensor. Specific examples of additional sensors include current sensors (e.g., VI probes), which may be affixed to one or more structural components such as a showerhead or pedestal, an in situ spectroscopic sensor configured to capture emitted radiation from a wafer or reactor component in the UV, visible, and/or IR spectrum (e.g., an optical emission spectroscopy sensor (OES)), and in situ optical metrology tool such as a reflectometer.

One example of an additional sensor is a capacitive voltage sensor having a relatively high input impedance. One example of an additional sensor is an inductive current transformer having a relatively low input impedance that occasionally or periodically samples a current conducted from an RF signal generator without bringing about any significant voltage drop. In some embodiments a current or voltage sensor is coupled in series between RF signal generator and a multi-station fabrication tool.

### Camera Image Analysis

Image analysis logic is configured to receive inputs including sensed values from one or more camera sensors on a fabrication tool. In certain embodiments, the sensed values include pixel-by-pixel intensity values as a function an observable parameter such as wavelength, time, polarization, or any combination thereof. In certain embodiments, input data from a camera sensor is provided in the form of image data, video data, spectral values, time series data, wafer metrology data and the like. In some embodiments, the input data is filtered by wavelength, polarization, etc. In some embodiments, analysis logic is configured to receive and act on additional input information beyond camera sensor intensity data. Such additional input information may include metadata about the camera sensor and/or associated camera components, substrate metrology information, historical information about the fabrication tool, etc.

The analysis logic may be configured to output one or more properties of a component in a fabrication tool, a process condition in a fabrication tool, and/or a classification of a state of the fabrication tool or a component thereof. Some examples of properties were presented above. In some embodiments, the analysis logic is configured as a classifier for diagnostic purposes, for predictive purposes, or for control purposes. Examples of diagnostic classifications include fault detection and anomalous conditions detection. Examples of predictive classifications include process or mechanical drift (e.g. a varying shape of a showerhead or other component) and associated predictive maintenance (generated by, e.g., regression analysis). Further examples are provided in U.S. Patent Application No. 63/113,133 filed Nov. 12, 2020, which is incorporated herein by reference in its entirety. Examples of control classifications include recommended modifications to apparatus or processes.

Camera sensor analysis logic may include any of various types of classifiers or models such as deep neural networks (e.g., convolutional neural networks, autoencoders, UNet, etc.), traditional or classical computer vision methods such as edge detection, image modification (such as blurring, changing contrast), intensity thresholding, color channel thresholding, etc.

Analysis logic may be configured to perform an image processing routine such as a segmentation or other edge finding routine. The logic may employ a threshold-based method, an edge detection method, etc. In some embodiments, the edge of a tool component or the boundary of a subregion within a tool component may be determined using a processing sequence such as the following: (a) data reduction, (b) denoising (e.g. gaussian blur), and (c) edge finding/thresholding (e.g., a Canny sequence of filter).

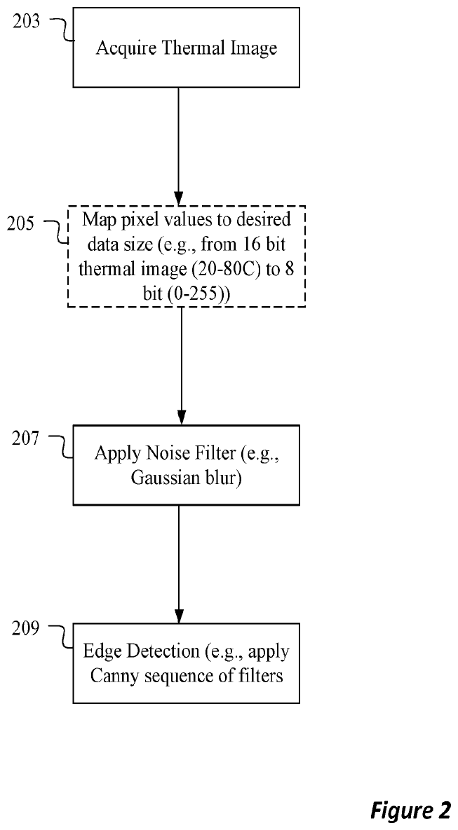

In some embodiments, an edge finding routine may be implemented using one or more computational operations from the following sequence. An example of an image processing sequence is depicted in FIG. 2.
1. Initially, a camera sensor acquires a thermal image of an interior region of a fabrication tool, an exterior region of a fabrication tool, and/or a component of the fabrication tool. See e.g., block 203. The image, as provided to analysis logic, may digitally represent, at pixel level resolution, the temperatures of points in the image. As an example, a thermal image may provide pixel data as thermal values (e.g., about 20-80° C.) in 16 bit values. This representation may be referred to as a thermal palette.
2. To reduce the quantity of data being processed, some image analysis routines may reduce the size of the data words representing pixel temperature values. See e.g., block 205. For example, a routine may map 16 bit values to 8 bit values.
3. In some implementations, an image analysis routine preprocesses the image to denoise it. See e.g., block 207. This process may remove some fine details that are not important to analyses based on thermal images. An example of a denoising algorithm is a Gaussian blur algorithm which blurs an image by applying a Gaussian function. In various embodiments, any one or more of various filters (implemented as, e.g., kernels) may be employed in place of or together with a Gaussian blur function.
4. In various embodiments, edge finding logic is configured to find edges of tool components or other features using a routine that operates on a denoised representation of a thermal image. See e.g., block 209. An example of an edge finding routine is a Canny edge detector. A Canny routine may employ the following sequence:
Find the intensity gradients of the image
Apply gradient magnitude thresholding or lower bound cut-off suppression to get rid of spurious response to edge detection
Apply double threshold to determine potential edges
Track edge by hysteresis: Finalize the detection of component edges by suppressing all the other potential edges that are weak and not connected to strong edges.
Elements bounded by edges may be denoted as objects for further analysis and processing.

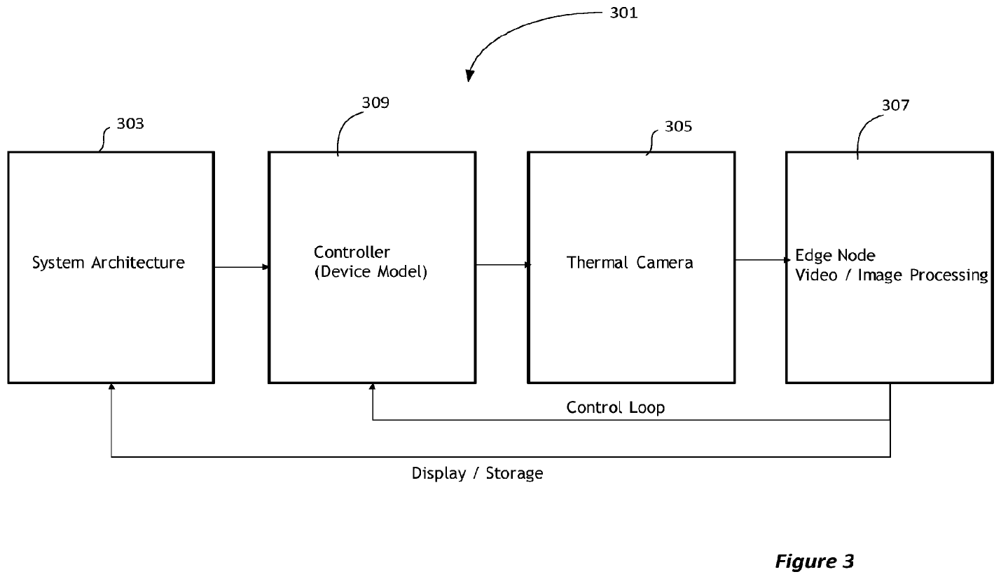

FIG. 3 depicts a system 301 with image analysis logic coupled to or integrated with an internal control system for controlling a fabrication tool. The combined logic may implement feedforward and/or feedback process control.

In the depicted embodiment, a thermal imager as depicted at a block 305 is configured to capture thermal camera images. It may be used in place of a thermocouple or other point-based sensor in a conventional system. The thermal imager may be a camera sensor integrated with a fabrication tool as described elsewhere herein.

Analysis of thermal images from imager 305 may be conducted, frame to frame, by an image data processor as illustrated at a block 307. The image data processor may represent all or a portion of image analysis logic employed by control system 301.

Images from imager 305 capture thermal information over a wide area. This allows analysis logic (e.g., data processor 307) to computationally analyze a combined temperature value (e.g., an average temperature) over multiple points in a region of a fabrication tool. In addition, or alternatively, it allows analysis logic to computationally analyze a temperature distribution over a region of a fabrication tool. Thus, the analysis logic may more fully evaluate thermal conditions as compared to analysis based on point specific information such as readings from a thermocouple or other point-based detector.

Data processor 307 may be configured to output temperature information about a region and/or a component of the fabrication tool. In some implementations, the output temperature data information is in the form of a scalar. In other cases, the output data is in the form of multidimensional vector or other form. In some embodiments, data processor 307 is configured to output temperature information at a high rate, e.g., in real time (e.g., at about 27 Hz or about one value every 40 ms).

Regardless of its form, information output by image data processor 307 may be provided to a system controller 309 that is configured to compare a current temperature value provided by data processor 307 to a temperature set point provided by recipe for the process currently being conducted. The temperature set point may be provided by or based on a device model.

Controller 309 is configured to determine an indicator of the difference between a current temperature as determined by image data processor 307 and the set point. Controller 309 is also configured to determine whether the temperature difference indicator (if any) requires an adjustment to a process control input to the fabrication tool. The controller may be configured to maintain and/or adjust process conditions within the fabrication tool.

Any adjustments may be made via a controller or control subsystem for one or more fabrication tool inputs. As an example, a control subsystem may be a heater control configured to, e.g., directly control the temperature of a wafer pedestal or a portion thereof. In general, the controller 309 drives associated fabrication tool component(s) to implement a process condition or adjustment, e.g., as by closed loop control logic.

In some embodiments, a control system employs a model that provides an additional level of control to the closed loop control algorithm. The model may be specific for a particular recipe (e.g., depositing silicon oxide from a particular precursor via an ALD process). In some implementations, multiple recipe-specific models are available for a control system to use. In some control systems, a system architecture block 303 is responsible for recipe setup, tool configurations, the system UI, a data logger, etc.

In the embodiment of FIG. 3, the system architecture 303 contains recipe-specific control parameters that may be provided to a model-based control to implement a feedforward control method that anticipates a future change in conditions and provides for a proactive adjustment. Adjustments to setpoints or overrides of setpoints may be provided via such a feedforward system. As an example, an output of a model-based control is combined with the output of the controller 307 via a control parameter adjustment logic to provide final value of the control parameter to the fabrication tool.

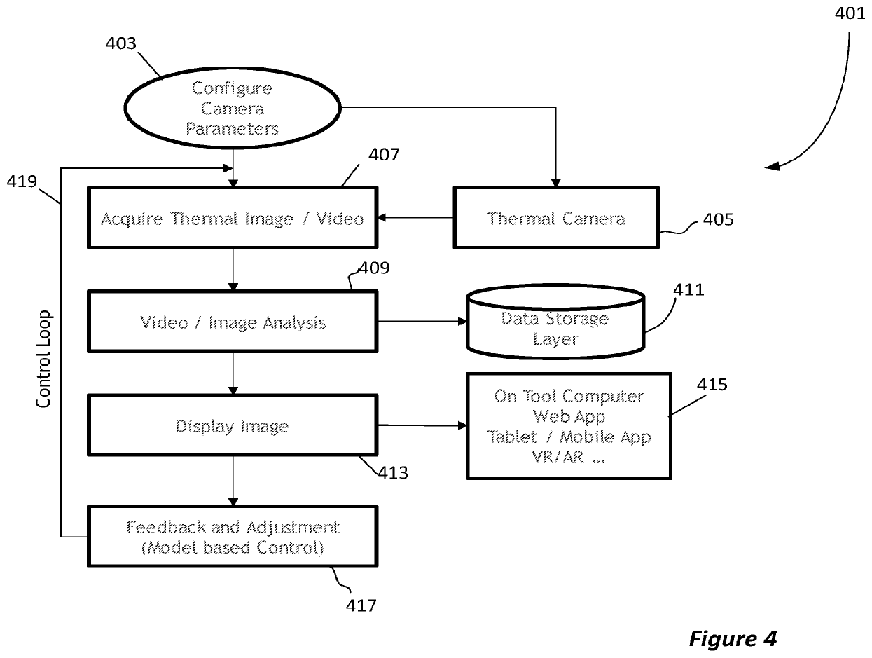

FIG. 4 presents a flow chart 401 illustrating a sequence of operations that may be employed to control and use image data (e.g., IR image data) from one or more camera sensors configured to capture images of a fabrication tool. System control logic may be employed to execute the various depicted operations.

Initially, the process 401 configures camera parameters at a block 403. This applies camera parameter to a thermal imager 405, e.g., an IR camera sensor as described herein. At this point, the system is ready acquire and process thermal images from thermal imager 405. The main process flow enters via a block 407, where control logic acquires one or more one or more thermal or palette images from the thermal imager 405. Transferring images may be accomplished via an API. Additionally, as illustrated at a block 409, the control logic processes, analyzes, and/or saves video frames. Examples of the processing include lossy compression routines. The resulting processed images may have a standard format such as JPEG, MPEG (e.g., mp4), AVI, or h284. They may be stored in a repository such as data storage 411 depicted in FIG. 4. Additionally, as illustrated at a block 413, the control logic may be capable of displaying images and/or video to a monitor or other display device 415, which may be part of any system or computing device such as an on-tool display or computer, a tablet, and/or an virtual or augmented reality device. Raw and/or processed images/video may be provided to display device 415 via software elements such as web browsers, mobile device apps, etc.

Still further, the control logic analyzes throughput or other process metric and provides an appropriate prediction, diagnosis, or control parameter. See block 417. The control logic for implementing this operation may correspond to image analysis logic described elsewhere herein. In some cases, the analysis logic at block 417 compares information acquired from a thermal or palette image to a setpoint or prediction in order to provide process control of a parameter in the fabrication tool. Analysis logic may be configured to use one or more characteristics of thermal images for any of various diagnostic, maintenance, and/or control functions. For example, the characteristic may be used for feedforward or feedback process control that involves adjusting a process condition or tool component to affect processing of a current or future substrate.

The sequence of operations 407, 409, 413, and 417 may be associated with one or more thermal images acquired at a defined time or time increment. The process repeats for multiple times as illustrated by the loop 419 in process 401.

A process for analyzing and/or using thermal images (e.g., process 401 of FIG. 4) may be implemented in a single-threaded or a multithreaded manner. For example, when implemented in a multi-threaded manner, the logic may employ parallel process loops for acquiring thermal images and for processing/displaying such images. Each such loop may include an operation for analyzing thermal images to draw a conclusion regarding any of various diagnostic, maintenance, and/or control functions.

In some implementations, various machine learning techniques may be applied to analyze and/or process thermal images. For example, in some embodiments, a trained machine learning model (e.g., a convolutional neural network, or other type of architecture) that is configured to perform segmentation on input thermal images may be used to identify objects or components (e.g., a showerhead, a pedestal, a lift pin, a wafer, etc.) present in the thermal image. Such a machine learning model may take, as an input, a thermal image, and generate, as an output, a segmented image that classifies pixels of the thermal image as belonging to different categories or classes, each associated with a different type of component or object. In some implementations, a trained machine learning model that generates a segmented thermal image may be used in conjunction with a classification algorithm (e.g., a support vector machine, a logistic regression, a k-nearest neighbors algorithm, etc.) to classify pixel clusters of the segmented thermal image. Note that, the segmented thermal image may be used for various purposes. For example, after a given component has been identified using the segmented thermal image, the temperature of the component may be monitored over time, the height or position of the component may be monitored over time, an area of a component may be determined, etc. In some embodiments, object detection may be performed (which may be performed on an un-segmented thermal image) to detect one or more different objects (e.g., various chamber components).

In some implementations, machine learning techniques may be used to sharpen blurry thermal images (e.g., to increase resolution). The sharpened thermal images may then be used for various purposes, such as to monitor the temperature and/or position of components of the system. In some embodiments, image sharpening may be performed using a generative adversarial network (GAN). A GAN is a machine learning architecture that includes a generator network that is trained to generate fake images and a discriminator network that is trained to discriminate between real images (e.g., real camera images) and fake images generated by the generator network. By training the generator network and the discriminator network in tandem, the generator network, once trained, may be configured to produce highly realistic fake images. Note that, at inference time, only the trained generator network is utilized to generate the fake images. To sharpen blurry images, the GAN may be trained using two sets of images, a set of high resolution thermal images (e.g., captured using a relatively high end mid-wavelength IR camera or similar), and a set of lower resolution thermal images. The lower resolution thermal images may be obtained using the same type or a similar type of thermal camera as that may be deployed during field use, while the higher resolution images may be obtained using a high-end camera that is not to be deployed during field use and is generally used for testing the system, training the GAN or other models, etc. The generator network of the GAN may be trained to take a lower resolution image as input and generate a corresponding higher resolution image as an output. Accordingly, when used at inference time, a relatively lower-resolution image (e.g., obtained using a relatively low-end camera) may be provided as an input to a trained generator network. The trained generator network may then generate a corresponding higher-resolution image that is, e.g., sharper than the lower-resolution image. The higher-resolution image may then be used for monitoring temperatures of different components, tracking or monitoring positions of different components, etc.

### Use Cases and Applications

Hot or cold regions identified via a camera image may indicate a deviation indicating an abnormal process condition or an abnormal condition of a tool component such as a worn component or loose components. In some embodiments, one or more camera sensors and associated analysis logic are configured to detect hot spots or cold spots in one or more chamber components. For example, analysis logic may be configured to identify a hot spot having characteristics that indicate electrical arcing. In another example, analysis logic may be configured to identify a hot spot or cold spot associated with crack in a component.

A crack or other defect in a component can give rise to a leak in the component. For example, cooling fluid may leak from a crack in a pedestal or process gas may leak from a crack in the stem of a showerhead. Some embodiments employ IR or temperature monitoring to detect leaks in tool components. For example, camera sensor analysis logic may be configured to analyze camera images in a way that detects leaks on pedestal backside or a showerhead backside. In some cases, such crack or leak is not detectable using visual inspection or conventional sensing technology. For example, a typical thermocouple provides only local measurement that may miss a crack propagating from a distant location, while a camera can provide a two-dimensional map of hotspots, cold spots, leaks, etc.

By using a camera sensor, IR-based leakage detection can be implemented in a non-obstructive/non-intrusive way. A thermal shift such the occurrence of temperature gradient may show up in a camera image at the location of a crack or defect. Depending on the process conditions and tool design, a crack or other defect may appear hotter or colder than expected or than compared to surrounding or adjacent regions. In some implementations, a crack, leak, or other defect is detectable by comparing a baseline thermal image against current thermal images and identifying trends or abrupt changes (over time) from the baseline image. If the image varies by more than a threshold amount (e.g., more than a defined change in temperature or wavelength), the analysis logic flags the issue or implements a mitigation strategy such as shutting down the tool or ordering a replacement part. If the change is abrupt or dramatic, imminent failure may result, which may necessitate dramatic action such as ceasing operation. While if the change is gradual, it may be predictive of a future failure, which necessitates a less dramatic reaction such a preventative maintenance or scheduling a part replacement during the next service opportunity.

In fabrication tools, a component such as a gas supply line, manifold, or showerhead stem may be wrapped in a heater, which can make it difficult to notice a leak, crack, or other defect in the component, particularly if the only sensor is a point sensor such a thermocouple. For detecting problems in a wrapped component, a thermal camera sensor may provide a revealing view of the component or component portion.

In some implementations, analysis logic is configured to analyze a thermal camera image of a substrate to be processed in a fabrication tool. The analysis logic may use such image to identify and/or interpret a local temperature level and/or a temperature distribution of the substrate upon entry to the fabrication tool, at any point during processing, or after processing. In some embodiments, before processing, the analysis logic analyzes a thermal camera image obtained from the wafer in a wafer handler outside a heated fabrication tool in order to qualify the wafer for processing or determine whether a preprocessing operation should be executed before moving the wafer into a fabrication tool or before processing within the tool. As a further example, the analysis logic may determine that the wafer is too cold to be safely inserted into the heated tool.

In some cases, a camera sensor trained on a wafer or wafer holder inside a fabrication tool provides images of the wafer prior to processing. Associated analysis logic may be configured to determine the temperature (e.g., an average or mean temperature) of the wafer and, from this information, determine a “soak” time for the wafer. Soak refers to the time that a wafer sits in a chamber, at a given temperature, prior to processing. Normal processing in a heated fabrication tool may require a soak for defined amount of time based on incoming substrate temperature. Wafer temperature may vary depending on various circumstances. For example, a wafer may have to sit in a transfer module for an extended period before it can enter the fabrication tool. While sitting, its temperature may drop to a level that requires a higher than normal amount of heating before processing. As a consequence of such variations, different soak times may be required for different temperature wafers in order than any given wafer is at a correct temperature when processing commences. In some embodiments, analysis logic is configured to detect from a wafer's thermal image the wafer's temperature and use that information to determine the soak time. If, for example, the logic determines that the wafer's temperature is unexpectedly low, the logic may determine that the soak time for this wafer should be approximately double the normal or baseline soak temperature.

In some embodiments where a separate pre-heat module is available, thermal sensing can allow for wafer transfer robots to do dynamic scheduling of wafer movement to minimize the heat lost due to sitting idle on the wafer transfer module waiting for it to enter a process chamber. Note that a pre-heat module is used at times when room temperature wafers must be moved into a process chamber where hot processing occurs. A pre-heat module in the chamber or a separate pre-heat chamber may be configured to slowly heat the wafer to minimize thermal shock.

In some embodiments, a detected substrate temperature distribution is compared against an expected temperature distribution to assess whether the current process is producing an expected level of uniformity (or non-uniformity). Based on such comparison, analysis logic may flag or adjust the process conditions or identify an issue with a fabrication tool component. In some embodiments, thermal image analysis of wafers supplements or replaces metrology measurements.

In some embodiments, one or more camera sensors and associated image analysis logic are configured to map flow patterns of a gas in a fabrication tool. Such gas may enter the tool from a showerhead and exit through a vacuum pump line. While in the tool, the flow pattern of the gas can significantly influence substrate processing. The flow pattern may be characterized by the gas' flow direction, flow velocity, etc. Analysis logic may be configured to determine these or other gas flow properties, optionally in real time, by analyzing one or more camera images. In some implementations, the analysis logic is configured to receive images such as IR camera images of one or more regions in a fabrication tool where gas flows during process (e.g., in a gap between a showerhead and wafer pedestal, around the perimeter of the showerhead, proximate a vacuum outlet line, etc.). Alternatively, or in addition, the logic may be configured to receive images of tool components whose temperature is influenced by flow patterns. Using any such images, the analysis logic may characterize the gas flow pattern within the tool. In some implementations, the analysis logic includes (or is configured to provide data to) a flow simulation model trained to use camera images or data derived therefrom to assess flow conditions. Such models may interpret temperature signatures in tool components or flow paths and characterize a process gas' flow direction, velocity, and/or other characteristics. In some embodiments, the camera sensor(s) and associated analysis logic are configured to make such assessments in real time during a fabrication operation. The analysis logic may be further configured to diagnosis or predict an issue with a tool component; e.g., a pump vent is partially clogged. In some embodiments, the model is a reduced order model that is relatively computationally simple and can assess flow conditions on, e.g., the order of milliseconds from the time an image is captured or provided to the model.

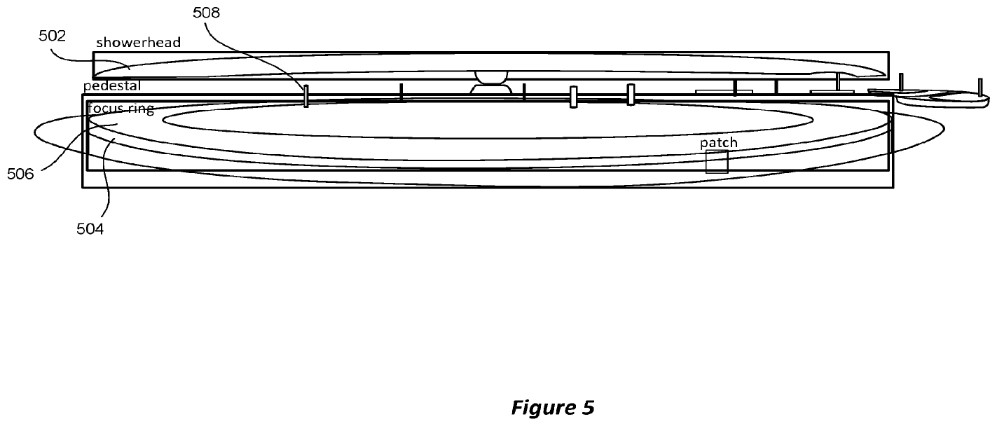

FIG. 5 is an example of a thermal image that may be used to monitor temperatures of various components of a process station or process chamber. As illustrated, the thermal image indicates a temperature of a showerhead 502, a pedestal 504, and a focus ring 506 corresponding to a position of a wafer when residing on pedestal 504. Additionally, the thermal image indicates the temperature of lift pins, such as lift pin 508. In some cases, the temperature of the various components may be used for various purposes. For example, when present, the temperature of a wafer may be tracked to monitor the change in temperature of the wafer when placed on the pedestal.

In some implementations, the thermal images may be used to monitor a status of components separately from the temperature of the components. For example, the thermal images may be used to determine a height of the pedestal. As another example, the thermal images may be used to determine positions, or relative positions of lift pins. By way of example, if lift pins are at different heights relative to each other, a wafer may break. Continuing with this example, relative positions of lift pins may be monitored using thermal images to detect drifts in the system that cause the lift pins to drift in height relative to one another, thereby preventing wafer breakage.

In some implementations, a tracer is included in a process gas (or a test gas) and camera images of the flowing tracer are used by analysis logic to characterize the gas' flow pattern. The tracer may have a detectable signature such as an emission spectrum, absorption characteristics, and/or reflection characteristics that can be captured by a camera sensor. In some embodiments, the camera sensors is equipped with one or more filters configured to detect spectral lines or regions.

Chamber cleaning processes may involve etching films from a fabrication tool's chamber walls and/or internal components. Such etching typically produces heat, and as a consequence the temperatures of the surfaces being cleaned tend to rise. In some applications, thermal imaging of the chamber walls and/or components during cleaning is used to monitor the progress and/or effectiveness of a chamber cleaning operation. Analysis logic may be configured to receive camera images of one or more portions or components of a fabrication tool that is being cleaned and determine whether the cleaning is being performed within specification. In some embodiments, analysis logic is configured to determine a temperature ramp over a time sequence of images from a fabrication tool being cleaned. The logic may be additionally configured to determine whether the temperature ramp indicates that the cleaning process is acceptable or has an issue that requires adjustment of the cleaning process, recleaning, or other operation.

In some implementations, one or more camera sensors are located and oriented to capture multiple features at distinct locations within a fabrication tool. For example, camera sensors may be arranged to capture at least ten such features. These features may be particular components within a tool, or particular portions of components (e.g., edges, seams, cavities, etc.), or particular points on components. Image analysis logic may be configured to characterize such features collectively at different points in time. The logic may be configured to compare the collective features over time to identify trends that might necessitate a change to process conditions or a tool component. For example, if the analysis logic detects a significant thermal property change in one or more features, the logic may trigger a diagnostic, control, and/or predictive response that may result in maintenance, part replacement, process condition/recipe adjustment, taking the tool out of service, etc.

In some implementations, analysis logic is configured to analyze multiple regions of interest within the interior of a fabrication tool. As an example, analysis logic is configured to analyze a gap between a wafer support and a showerhead or other gas delivery component. In some embodiments, the regions of interest are separated from one another along a horizontal axis parallel to a substantially planar surface of a pedestal or showerhead. In some embodiments, the regions of interest are distributed along a vertical axis in the gap and perpendicular to a substantially planar surface of a pedestal or showerhead. In other examples, analysis logic is configured to identify multiple regions of interest on a particular component or components within a fabrication tool.

In certain embodiments, the analysis logic receives a time series of images from one or more camera sensors and, based at least in part on these images, determines a current state or a change in condition within a fabrication tool. In some cases, analysis logic is configured to compare camera sensor images obtained over a period of time that spans processing of two or more substrates, or spans processing of two or more batches of substrates, or spans processing of substrates before and after a fabrication tool is cleaned or serviced. In some cases, analysis logic is configured to compare camera sensor images obtained over a period of time that spans processing of a single substrate.

In some implementations, analysis logic is configured to compare a current image or collection of images to a baseline or “gold” image obtained for (or representing) a baseline process condition, and/or a baseline fabrication tool state, and/or a baseline tool component state. The baseline may correspond to a known state such as a state in which the process and/or tool are performing acceptably or optimally. If the analysis logic determines that a current image has more than a defined level of deviation from a baseline image, it may flag the tool or operation for further analysis and/or shut down operation of the process or the tool. The deviation may be based on thermal imaging as discussed herein. Among the conditions that may cause a significant deviation from the baseline are a tool component is worn or broken (e.g., cracked), gas composition and/or flow characteristics have deviated from specification, a plasma generation component is malfunctioning, etc.

In some applications, camera sensor analysis logic is configured to compare thermal properties from station-to-station in a multi-station fabrication tool. In some implementations, camera sensors are positioned and oriented to capture images of the same hardware components (e.g., vents, valves, spindles, etc.) in each of multiple stations. Analysis logic is configured to compare the sensor images across the multiple stations. If the analysis logic detects a thermal variation in any of the stations, the logic may trigger a diagnostic, control, and/or predictive response that may result in a change to the station exhibiting the variation. The change may involve maintenance, part replacement, process condition/recipe adjustment, etc.

In various applications, one or more camera sensors and associated analysis logic are configured to assess the temperature uniformity of parts within a fabrication tool and/or a station within a multi-station fabrication tool. In some embodiments, the camera sensors are located and oriented to capture thermal images of individual stations of a multi-station fabrication tool. The logic may be configured to compare the temperatures or temperature distributions in the individual stations and assess whether any of the stations is operating at a temperature or other condition that is out of specification or significantly deviant from that of the other stations. With this information, analysis logic may direct a change in a station of a multi-station fabrication tool. Such change may include a change in process conditions in the station or maintenance or replacement of one or more components in the station.

A camera sensor may be located at any of various positions on or around a fabrication tool to capture images of features that might not be otherwise easily viewed. In some embodiments, a camera sensor is disposed at the top of the fabrication tool. This may provide images that include a portion of a showerhead (e.g., a showerhead stem). In the case of a multi-station tool, one or more camera sensors may be located to capture images of the multiple showerhead stems of individual stations in the tool. For example, one or two camera sensors may be located on top of a four-station tool and be configured to capture images of all four showerheads. In some cases, one, two, or more cameras are located on the bottom of a fabrication tool to capture images of one or more substrate pedestals (e.g., multiple pedestals in the case of a multi-station fabrication tool). The images may show pedestal stems or other features of the backsides of pedestals. In some cases, a camera sensor is configured and oriented to capture images in a field of view that occupies at least about one quarter of a fabrication tool (e.g., when viewed from above or below).

In some applications, camera sensor analysis logic is configured to monitor or characterize process transitions, from step-to-step in a process conducted in a fabrication tool. Camera images of the plasma state during process transitions may allow calibration or matching of other sensors (e.g., non-camera sensors such as VI sensors) or sensor results in the fabrication tool.

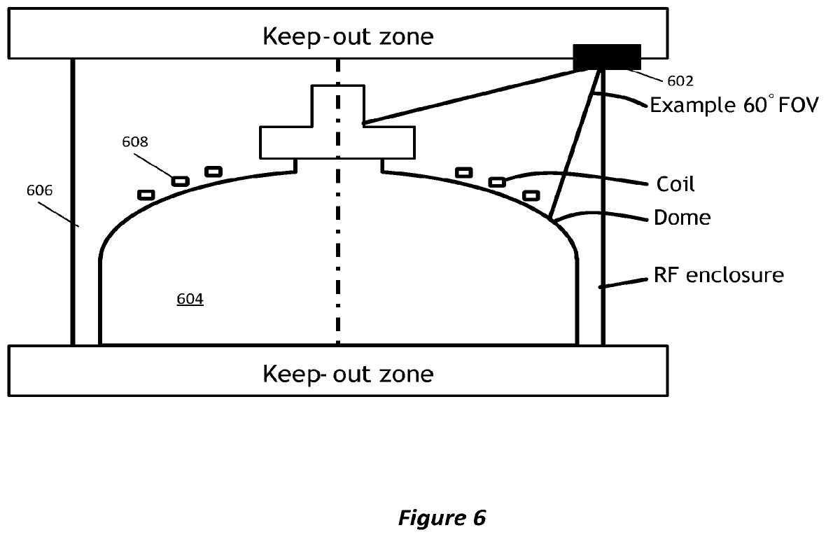

An example use case of monitoring a temperature at various points of a plasma formation receptacle is illustrated in FIG. 6. As illustrated, a camera 602 may be configured to acquire images of a plasma formation receptacle 604 and surrounding regions. For example, camera 602 may have a field of view of, e.g., 50 degrees, 60 degrees, 70 degrees, etc. The images may include portions of a surface of plasma formation receptable 602, regions proximate to the surface of plasma formation receptacle 602, regions proximate to RF enclosure 606, coils 608, or the like.

In some cases, a plasma formation receptacle may be made of ceramic, which may be prone to cracks or other types of breaking if the temperature of the ceramic exceeds a threshold temperature or has a temperature rate of change greater than a threshold rate. Accordingly, images from a thermal camera may be used to monitor the temperature, or the rate of change of the temperature, of the plasma formation receptacle to prevent cracks or breaking.

In some implementations, temperature may be monitored or determined using thermal camera images, where the temperature is monitored for a curved surface, such as a plasma formation receptacle that is, e.g., dome-shaped (as shown in FIG. 6). Because curvature may affect temperature in a manner that is dependent on the angle of curvature among other factors, a calibration procedure may be performed to convert between measurements obtained from thermal camera images (e.g., intensity in various IR bands) to temperature. The calibration procedure may involve measuring the temperature of an object having a similar curvature using, e.g., a thermocouple. An example of an object that may be used to perform curvature calibration for a dome-shaped plasma formation receptacle is a cooking pot or other similarly shaped object. By way of example, a calibration procedure using a cooking pot may involve heating the cooking pot and measuring temperature within boiling water as the boiling water cools using a thermocouple. The thermocouple measurements may then be used to calibrate concurrent thermal camera images in order to calibrate thermal analysis logic for use in monitoring temperature of a plasma formation receptacle. In some embodiments, thermal analysis logic may utilize a cosine function or other function that can account for curvature of the receptacle and viewing angles of the thermal imaging camera.

### Sensor Analysis Logic

Systems including fabrication tools as described herein may include logic for characterizing a plasma in fabrication tool. The analysis logic may be configured to receive signals from a camera sensor by, e.g., analog and/or digital input connections.

The analysis logic may be designed and implemented in any of various ways. For example, the logic can be implemented in hardware and/or software. Examples of hardware and software implementations of logic are presented below in this section and in the controller section. Hardware-implemented analysis logic may be provided in any of various forms, including hard coded logic in digital signal processors, application-specific integrated circuits, and other devices that have algorithms implemented as hardware. Software-implemented analysis logic may be provided in any of various forms, including software or firmware instructions configured to be executed on a general-purpose or a special-purpose processor. System control software may be provided by “programming” in a computer readable programming language.

The computer program code for controlling processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

Integrated circuits used in analysis logic may include chips in the form of firmware that store program instructions, digital signal processors (DSPs), chips defined as application specific integrated circuits (ASICs), and/or one or more microprocessors or microcontrollers that execute program instructions (e.g., software). Program instructions may be instructions communicated in the form of various individual settings (or program files), defining operational parameters for carrying out a particular analysis (e.g., image analysis) application.

In some implementations, image analysis logic is resident (and executes) on or is closely associated with a computational resource of a fabrication tool from which thermal images are captured. As an example, image analysis logic may execute on an edge computer associated with a fabrication tool. In some implementations, the image analysis logic is remote from a fabrication tool from which thermal images are captured. For example, the analysis logic may be executable on cloud-based resources.

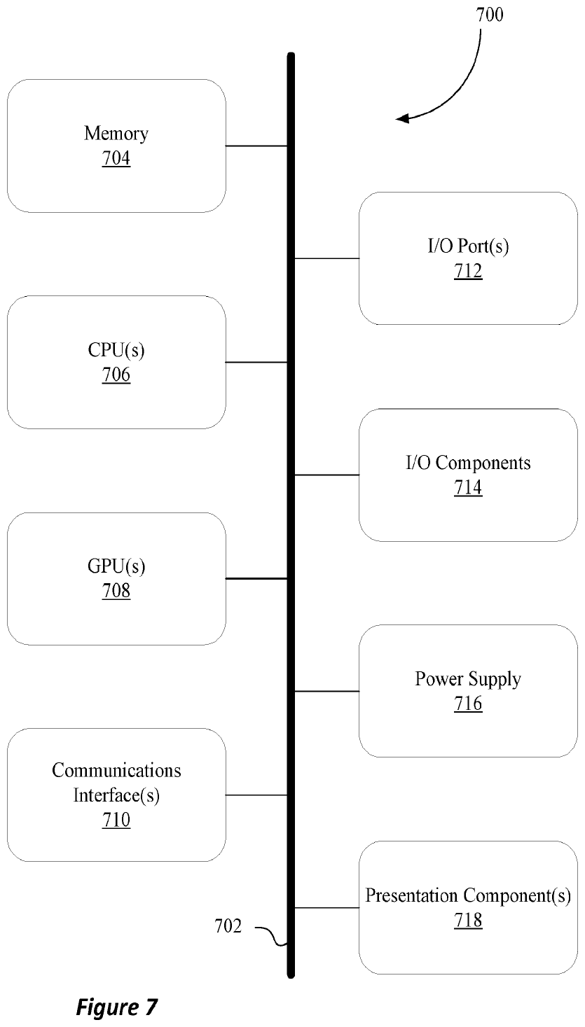

FIG. 7 is a block diagram of an example of the computing device 700 suitable for use in implementing some embodiments of the present disclosure. For example, device 700 may be suitable for implementing some or all functions of image analysis logic disclosed herein.

Computing device 700 may include a bus 702 that directly or indirectly couples the following devices: memory 704, one or more central processing units (CPUs) 706, one or more graphics processing units (GPUs) 708, a communication interface 710, input/output (I/O) ports 712, input/output components 714, a power supply 716, and one or more presentation components 718 (e.g., display(s)). In addition to CPU 706 and GPU 708, computing device 700 may include additional logic devices that are not shown in FIG. 7, such as but not limited to an image signal processor (ISP), a digital signal processor (DSP), an ASIC, an FPGA, or the like.

Although the various blocks of FIG. 7 are shown as connected via the bus 702 with lines, this is not intended to be limiting and is for clarity only. For example, in some embodiments, a presentation component 718, such as a display device, may be considered an I/O component 714 (e.g., if the display is a touch screen). As another example, CPUs 706 and/or GPUs 708 may include memory (e.g., the memory 704 may be representative of a storage device in addition to the memory of the GPUs 708, the CPUs 706, and/or other components). In other words, the computing device of FIG. 7 is merely illustrative. Distinction is not made between such categories as “workstation,” “server,” “laptop,” “desktop,” “tablet,” “client device,” “mobile device,” “hand-held device,” “electronic control unit (ECU),” “virtual reality system,” and/or other device or system types, as all are contemplated within the scope of the computing device of FIG. 7.

Bus 702 may represent one or more busses, such as an address bus, a data bus, a control bus, or a combination thereof. The bus 702 may include one or more bus types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus.

Memory 704 may include any of a variety of computer-readable media. The computer-readable media may be any available media that can be accessed by the computing device 700. The computer-readable media may include both volatile and nonvolatile media, and removable and non-removable media. By way of example, and not limitation, the computer-readable media may comprise computer-storage media and/or communication media.

The computer-storage media may include both volatile and nonvolatile media and/or removable and non-removable media implemented in any method or technology for storage of information such as computer-readable instructions, data structures, program modules, and/or other data types. For example, memory 704 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 700. As used herein, computer storage media does not comprise signals per se.

The communication media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the communication media may include wired media such as a wired network or direct-wired connection, and wireless media such as acoustic, RF, infrared and other wireless media. Combinations of any of the above should also be included within the scope of computer-readable media.

CPU(s) 706 may be configured to execute the computer-readable instructions to control one or more components of the computing device 700 to perform one or more of the methods and/or processes described herein. CPU(s) 706 may each include one or more cores (e.g., one, two, four, eight, twenty-eight, seventy-two, etc.) that are capable of handling a multitude of software threads simultaneously. CPU(s) 706 may include any type of processor and may include different types of processors depending on the type of computing device 700 implemented (e.g., processors with fewer cores for mobile devices and processors with more cores for servers). For example, depending on the type of computing device 700, the processor may be an ARM processor implemented using Reduced Instruction Set Computing (RISC) or an x86 processor implemented using Complex Instruction Set Computing (CISC). Computing device 700 may include one or more CPUs 706 in addition to one or more microprocessors or supplementary co-processors, such as math co-processors.

GPU(s) 708 may be used by computing device 700 to render graphics (e.g., 3D graphics). GPU(s) 708 may include many (e.g., tens, hundreds, or thousands) of cores that are capable of handling many software threads simultaneously. GPU(s) 708 may generate pixel data for output images in response to rendering commands (e.g., rendering commands from CPU(s) 706 received via a host interface). GPU(s) 708 may include graphics memory, such as display memory, for storing pixel data. The display memory may be included as part of memory 704. GPU(s) 708 may include two or more GPUs operating in parallel (e.g., via a link). When combined, each GPU 708 can generate pixel data for different portions of an output image or for different output images (e.g., a first GPU for a first image and a second GPU for a second image). Each GPU can include its own memory or can share memory with other GPUs.

In examples where the computing device 700 does not include the GPU(s) 708, the CPU(s) 706 may be used to render graphics.

Communication interface 710 may include one or more receivers, transmitters, and/or transceivers that enable computing device 700 to communicate with other computing devices via an electronic communication network, included wired and/or wireless communications. Communication interface 710 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet), low-power wide-area networks (e.g., LoRaWAN, SigFox, etc.), and/or the internet.

I/O ports 712 may enable the computing device 700 to be logically coupled to other devices including I/O components 714, presentation component(s) 718, and/or other components, some of which may be built in to (e.g., integrated in) computing device 700. Illustrative I/O components 714 include a microphone, mouse, keyboard, joystick, track pad, satellite dish, scanner, printer, wireless device, etc. I/O components 714 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of computing device 700. Computing device 700 may be include depth cameras, such as stereoscopic camera systems, infrared camera systems, RGB camera systems, touchscreen technology, and combinations of these, for gesture detection and recognition. Additionally, computing device 700 may include accelerometers or gyroscopes (e.g., as part of an inertia measurement unit (IMU)) that enable detection of motion. In some examples, the output of the accelerometers or gyroscopes may be used by computing device 500 to render immersive augmented reality or virtual reality.

Power supply 716 may include a hard-wired power supply, a battery power supply, or a combination thereof. Power supply 716 may provide power to computing device 700 to enable the components of computing device 700 to operate.

Presentation component(s) 718 may include a display (e.g., a monitor, a touch screen, a television screen, a heads-up-display (HUD), other display types, or a combination thereof), speakers, and/or other presentation components. Presentation component(s) 718 may receive data from other components (e.g., GPU(s) 708, CPU(s) 706, etc.), and output the data (e.g., as an image, video, sound, etc.).

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

### Controller Embodiments

In some implementations, a “controller” is part of a system containing a camera sensor as described herein. Such systems include a fabrication tool with a camera sensor. The system may optionally additionally be integrated with electronics for controlling their operation before, during, and after processing of a substrate. The controller may be implemented with or coupled to analysis logic as described above. A controller may be implemented as logic such as electronics having one or more integrated circuits, memory devices, and/or software that receive instructions, issue instructions, control operation, and/or enable sensing operations.

A controller may be configured to control or cause control of various components or subparts of the system or systems. The controller, depending on the processing requirements and/or the type of system, may be programmed to control any of the processes that may be used by a fabrication tool during a fabrication operation, including adjusting or maintaining the delivery of processing gases, temperature settings (e.g., heating and/or cooling) including substrate temperature and chamber wall temperature, pressure settings including vacuum settings, plasma settings, RF matching circuit settings, and substrate positional and operation settings, including substrate transfers into and out of a fabrication tool and/or load lock. Process gas parameters include the process gas composition, flow rate, temperature, and/or pressure. Of particular relevance to the disclosed embodiments, controller parameters may relate to plasma generator power, pulse rate, and/or RF frequency.

Process parameters under the control of a controller may be provided in the form of a recipe and may be entered utilizing a user interface. Signals for monitoring the process may be provided by analog and/or digital input connections of the system controller. The signals for controlling the process are output on the analog and digital output connections of the deposition apparatus.

In one example, the instructions for bringing about ignition or maintenance of a plasma are provided in the form of a process recipe. Relevant process recipes may be sequentially arranged, so that at least some instructions for the process can be executed concurrently. In some implementations, instructions for setting one or more plasma parameters may be included in a recipe preceding a plasma ignition process. For example, a first recipe may include instructions for a first time delay, instructions for setting a flow rate of an inert gas (e.g., helium) and/or a reactant gas, and instructions for setting a plasma generator to a first power set point. A second, subsequent recipe may include instructions for a second time delay and instructions for enabling the plasma generator to supply power under a defined set of parameters. A third recipe may include instructions for a third time delay and instructions for disabling the plasma generator. It will be appreciated that these recipes may be further subdivided and/or iterated in any suitable way within the scope of the present disclosure. In some deposition processes, a duration of a plasma strike may correspond to a duration of a few seconds, such as from about 3 seconds to about 15 seconds, or may involve longer durations, such as durations of up to about 30 seconds, for example. In certain implementations described herein, much shorter plasma strikes may be applied during a processing cycle. Such plasma strike durations may be on the order of less than about 50 milliseconds, with about 25 milliseconds being utilized in a specific example. As explained, plasma may be pulsed.

In some embodiments, a controller is configured to control and/or manage the operations of a RF signal generator. In certain implementations, a controller is configured to determine upper and/or lower thresholds for RF signal power to be delivered to a fabrication tool, determining actual (such as real-time) levels of RF signal power delivered to integrated circuit fabrication chamber, RF signal power activation/deactivation times, RF signal on/off duration, duty cycle, operating frequency, and so forth.

As further examples, a controller may be configured to control the timing of various operations, mixing of gases, the pressure in a fabrication tool, the temperature in a fabrication tool, the temperature of a substrate or pedestal, the position of a pedestal, chuck and/or susceptor, and a number of cycles performed on one or more substrates.

A controller may include one or more programs or routines for controlling designed subsystems associated with a fabrication tool. Examples of such programs or routines include a substrate positioning program, a process gas control program, a pressure control program, a heater control program, and a plasma control program. A substrate positioning program may include program code for process tool components that are used to load the substrate onto a pedestal and to control the spacing between the substrate and other parts of a fabrication tool. A positioning program may include instructions for moving substrates in and out of the reaction chamber to deposit films on substrates and clean the chamber.

A process gas control program may include code for controlling gas composition and flow rates and for flowing gas into one or more process stations prior to deposition to bring about stabilization of the pressure in the process station. In some implementations, the process gas control program includes instructions for introducing gases during formation of a film on a substrate in the reaction chamber. This may include introducing gases for a different number of cycles for one or more substrates within a batch of substrates. A pressure control program may include code for controlling the pressure in the process station by regulating, for example, a throttle valve in the exhaust system of the process station, a gas flow into the process station, etc. The pressure control program may include instructions for maintaining the same pressure during the deposition of differing numbers of cycles on one or more substrates during the processing of the batch.

A heater control program may include code for controlling the current to a heating unit that is used to heat the substrate. Alternatively, the heater control program may control delivery of a heat transfer gas (such as helium) to the substrate.

In some implementations, there may be a user interface associated with a controller. The user interface may include a display screen, graphical software displays of the apparatus and/or process conditions, and user input devices such as pointing devices, keyboards, touch screens, microphones, etc.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

The system software may be organized in many different ways that may have different architectures. For example, various chamber component subroutines or control objects may be written to control operation of the chamber components necessary to carry out the deposition processes (and other processes, in some cases) in accordance with the disclosed embodiments.

### Additional Considerations

Without limitation, example systems for implementing the thermal image capture and/or processing described herein may include a plasma etch chamber or module, a deposition chamber or module such as a chemical vapor deposition (CVD) chamber or module, a plasma-assisted chemical vapor deposition (PECVD) chamber or module, an atomic layer deposition (ALD) chamber or module, a plasma-assisted atomic layer deposition (PEALD) chamber or module, an atomic layer etch (ALE) chamber or module, a clean chamber or module, a physical vapor deposition (PVD) chamber or module, an ion implantation chamber or module, and any other semiconductor processing system that may be associated or used in the fabrication and/or manufacturing of semiconductor wafers.

Unless otherwise specified, the plasma power levels and associated parameters provided herein are appropriate for processing a 300 mm wafer substrate. One of ordinary skill in the art would appreciate that these parameters may be adjusted as necessary for substrates of other sizes.

The apparatus/process described herein may be used in conjunction with lithographic patterning tools or processes, for example, for the fabrication or manufacture of electronic devices including semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

As used in this specification and appended claims, the singular forms “a”, “an”, and “the” include plural referents unless the content and context dictates otherwise. For example, reference to “a cell” includes a combination of two or more such cells. Unless indicated otherwise, an “or” conjunction is used in its correct sense as a Boolean logical operator, encompassing both the selection of features in the alternative (A or B, where the selection of A is mutually exclusive from B) and the selection of features in conjunction (A or B, where both A and B are selected).

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

Components or logic “configured to” perform an operation may be configured to perform such operation using software or hardware—for example, circuits, memory storing program instructions executable to implement the operation, etc. Additionally, a component or logic may be “configured to” perform an operation using a generic structure (e.g., generic circuitry) that is manipulated by software and/or firmware (e.g., an FPGA or a general-purpose processor executing software) to operate in manner that is capable of performing the recited operation(s). Additionally, a component or element “configured to” perform an operation can be configured by one or more memories or memory elements storing computer executable instructions for performing the recited task(s). Such memory elements may include memory on a computer chip having processing logic. In some contexts, the words “configured to” refer to adapting a manufacturing process (e.g., a semiconductor fabrication facility) to fabricate devices (e.g., integrated circuits).

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A system comprising:
a device fabrication process chamber comprising a chamber wall and a wafer support;
one or more optical access apertures in the process chamber;
one or more camera sensors optically coupled to the one or more optical access apertures; and
analysis logic configured to process signals from the one or more camera sensors to determine one or more thermal characteristics of a component in the process chamber.

2. The system of claim 1, wherein at least one of the one or more optical access apertures is disposed in the chamber wall and provides a generally vertical line of sight into the process chamber.

3. The system of claim 1, wherein at least one of the one or more optical access apertures is configured to provide a generally vertical line of sight into the process chamber.

4. The system of claim 3, wherein the at least one of the one or more optical access apertures is disposed in a top surface of the process chamber or in a bottom surface of the process chamber.

5. The system of claim 1, wherein the process chamber comprises at least two stations.

6. The system of claim 5, wherein the component in the process chamber is in a first station of the process chamber and wherein the analysis logic is configured to determine the one or more thermal characteristics of the component in the process chamber by accounting for an imaged feature located in a second station of the process chamber, wherein the first station and the second station are among the at least two stations of the process chamber.

7. (canceled)

8. The system of claim 1, further comprising a non-camera sensor, and wherein the analysis logic is configured to employ signals from the non-camera sensor to determine the one or more thermal characteristics of a component in the process chamber.

9. The system of claim 1, wherein the one or more camera sensors comprise a thermal imaging camera sensor.

10. (canceled)

11. The system of claim 1, wherein the camera sensor is configured to capture optical signals in the IR spectral region.

12.-17. (canceled)

18. The system of claim 1, wherein the component in the process chamber comprises a gas supply line, a showerhead, a valve, a vent, a substrate pedestal, a substrate chuck, a coolant line, an electrode configured to provide plasma power to the process chamber, a sensor, an exhaust line, an electrical connection, an accumulator, a heater, and/or a wall of the process chamber.

19. (canceled)

20. The system of claim 18, wherein the heater is connected to gas line, an accumulator volume, a vaporizer, an ampoule, an electrical connection, an exhaust line, or any combination of these.

21. The system of claim 1, wherein the analysis logic is further configured to compare a current image from the camera sensor with a baseline image.

22. The system of claim 21, wherein the analysis logic is further configured to use a comparison of the current image and the baseline image to identify a hot spot or a cold spot on the component of the process chamber.

23. The system of claim 22, wherein the analysis logic is further configured to identify a crack, leak, and/or wear in the component based on, at least in part, the hot spot or cold spot.

24. The system of claim 21, wherein the analysis logic is further configured to adjust a process condition and/or modify the process chamber in response to a temporal change in a comparison of the current image and the baseline image.

25. The system of claim 1, wherein the analysis logic is further configured to determine a temperature of a wafer in the process chamber.

26. The system of claim 25, wherein the temperature of the wafer is a temperature distribution on the wafer.

27.-31. (canceled)

32. The system of claim 1, wherein the signals from the one or more camera sensors comprise thermal images of the process chamber while it is being cleaned, and wherein the analysis logic is configured to characterize the process chamber undergoing cleaning and/or a condition of a cleaning operation.

33. The system of claim 1, wherein the analysis logic is further configured to determine one or more edges of the component in the process chamber.

34. The system of claim 33, wherein the analysis logic is configured to determine the one or more edges of the component in the process chamber by applying a noise filter to a thermal image of the component and then applying an edge finding routine to the thermal image.

35. (canceled)

36. The system of claim 1, wherein the one or more thermal characteristics of the component comprise a temperature distribution of the component.

37. The system of claim 1, wherein the analysis logic is further configured to determine, based at least partly on the thermal characteristics of the component, whether the component or a process condition in the process chamber is out of an acceptable range for continued operation without change.

38. The system of claim 1, wherein the analysis logic is further configured to cause to be performed, based at least partly on the thermal characteristics of the component, a correcting action.

39. The system of claim 38, wherein the analysis logic is further configured to compare information obtained from signals of the one or more camera sensors with a reference value and based on a magnitude of difference between the information and the reference value, determine the correcting action.

40. The system of claim 1, wherein the analysis logic is further configured to monitor the one or more thermal characteristics of the component temporally, and based on a rate of change of the one or more thermal characteristics, determine that the component or the process chamber is in a fault state.

41.-51. (canceled)

52. The system of claim 1, wherein to process the signals from the one or more camera sensors, the analysis logic is configured to use a trained machine learning model to sharpen an image associated with the signals from the one or more camera sensors.

53. The system of claim 52, wherein the trained machine learning model comprises at least a portion of a generative-adversarial network (GAN).

54. A system comprising:
a process chamber comprising a chamber wall and a wafer support;
one or more optical access apertures in the chamber wall;
one or more camera sensors optically coupled to the one or more optical access apertures in a manner that captures a two-dimensional image or a three-dimensional image of one or more features of a component located within the process chamber; and
analysis logic configured to process signals from the one or more camera sensors to (i) characterize one or more properties of the component at a first region of interest within the process chamber, and (ii) characterize the one or more properties of the component at a second region of interest within the process chamber.

55. A system comprising:
a process chamber, comprising a chamber wall and a wafer support;
an optical access aperture in the chamber wall;
a camera sensor optically coupled to the optical access aperture;
an auxiliary sensor configured to sense a thermal, optical, and/or electrical condition in the process chamber, wherein the auxiliary sensor is not a camera sensor, and
analysis logic configured to process signals from the camera sensor and the auxiliary sensor to characterize one or more thermal properties of a component in the process chamber.

56. A method comprising:
receiving signals from one or more camera sensors optically coupled to one or more optical access apertures of a device fabrication process chamber comprising a chamber wall and a wafer support; and
determining from the signals one or more thermal characteristics of a component in the process chamber.
